(19) United States
(12) Patent Application Publication
(10) Pub. No.: US 2008/0128825 A1
(43) Pub. Date: Jun. 5, 2008

(54) Semiconductor device and method for fabricating the same

(76) Inventors: Yoshihiro Sato, Hyogo (JP); Hisashi Ogawa, Osaka (JP)

Correspondence Address: MCDERMOTT WILL & EMERY LLP, 600 13TH STREET, NW, WASHINGTON, DC, 20005-3096, US

(21) Appl. No.: 11/979,870

(22) Filed: Nov. 9, 2007

(30) Foreign Application Priority Data
Nov. 30, 2006 (JP) 2006-323669

(51) Int. Cl. H01L 27/092; H01L 21/8238

(52) U.S. Cl. 257/369; 438/218; 257/E27.062; 257/E21.632

(57) ABSTRACT

A p-type MIS transistor includes a first gate insulating film formed on a first active region; and a first fully silicided gate pattern that is obtained by fully siliciding a silicon film, is formed to extend over the first active region with the first gate insulating film sandwiched therebetween, and includes a first fully silicided gate electrode provided on the first active region and a first fully silicided gate line provided on the isolation region. The first fully silicided gate pattern includes, along a gate width direction, a portion having a first thickness and including the first fully silicided gate electrode and portions each having a second thickness larger than the first thickness and respectively disposed on both sides of the portion having the first thickness.

### BACKGROUND OF THE INVENTION

The present invention relates to a semiconductor device and a method for fabricating the same, and more particularly, it relates to a semiconductor device having a fully silicided gate electrode and a method for fabricating the same.

In accordance with the recent technical development for higher integration, higher performance and higher speed of semiconductor integrated circuit devices, MISFETs have been more and more refined.

In a method earnestly examined in accordance with the refinement of MISFETs for further reducing the thickness of a gate insulting film and suppressing increase of a gate leakage current derived from a tunnel current, a high dielectric constant material made of a metal oxide such as hafnium oxide (HfO₂), hafnium silicate (HfSiO) or a hafnium silicate nitride (HfSiON) is used instead of SiO₂ or SiON conventionally used as a gate insulating film material, so that a leakage current can be suppressed with keeping a large physical film thickness while realizing a small thickness corrected as a silicon oxide film.

Furthermore, in order to prevent capacity lowering due to depletion of a gate electrode, metal materials to be used instead of conventionally used polysilicon are earnestly studied as gate electrode materials. Candidates for such metal materials are a metal nitride, a dual metal of two kinds of pure metals having different work functions and a fully silicided (FUSI) metal obtained by siliciding a whole silicon material. In particular, a fully silicided metal is regarded as promising technique because it is applicable to the current silicon process technique. A structure of a MISFET using such a fully silicided metal and a method for fabricating the same are disclosed in, for example, J. A Kittl et al., Symp. VLSI Tech., (2005) 72. and A. Lauwers et al., IEDM Tech. Dig., (2005) 661.

In MISFETs using a fully silicided gate electrode, an nMISFET and a pMISFET are distinguishably formed by controlling a composition ratio in the silicide of the fully silicided gate electrode. For example, assuming that nickel is used, a fully silicided gate electrode of an nMISFET necessary to have a comparatively small work function is preferably made of NiSi in which a composition ratio between nickel and silicon is 1:1, and a fully silicided gate electrode of a pMISFET necessary to have a comparatively large work function is preferably made of Ni₂Si, Ni₃Si or Ni₃₁Si₁₂.

A fully silicided gate electrode of an nMISFET and a fully silicided gate electrode of a pMISFET are distinguishably formed based on the thickness ratio between a silicon film formed for the gate electrode and a nickel film deposited on the silicon film. Specifically, assuming that a silicon film has a thickness tSi and a nickel film has a thickness tNi, the thickness ratio needs to satisfy a relationship of 0.55<tNi/tSi for forming a fully silicided gate electrode of an nMISFET, and the thickness ratio needs to satisfy a relationship of 1.1<tNi/tSi for forming a fully silicided gate electrode of a pMISFET. When annealing conditions (such as a temperature and time) for causing a reaction between the silicon film and the nickel film are controlled so as to attain such a thickness ratio, the composition ratio is controlled in the silicide of a fully silicided gate electrode of an nMISFET or a pMISFET, so that a fully silicided gate electrode of an nMISFET and a fully silicided gate electrode of a pMISFET can be distinguishably formed.

However, since a fully silicided material of Ni₂Si, Ni₃Si or Ni₃₁Si₁₂ used for a pMISFET has large specific resistance, when it is used in a gate line portion or the like disposed on an isolation region or the like, the interconnect resistance is so increased that the operation speed of a semiconductor integrated circuit including it is lowered. In other words, the specific resistance of a fully silicided gate line portion extending, on an isolation region, from a fully silicided gate electrode of a pMISFET formed on an active region surrounded with the isolation region is so large that the operation speed of the semiconductor integrated circuit is disadvantageously lowered.

### SUMMARY OF THE INVENTION

In consideration of the aforementioned conventional disadvantage, an object of the invention is, with respect to a semiconductor device including a MISFET having a fully silicided gate electrode, providing a semiconductor device having low gate line resistance and a method for fabricating the semiconductor device.

In order to achieve the object, the semiconductor device according to an aspect of the invention includes a p-type MIS transistor formed on a first active region surrounded by an isolation region in a semiconductor substrate, and the p-type MIS transistor includes a first gate insulating film formed on the first active region; and a first fully silicided gate pattern that is obtained by fully siliciding a silicon film, is formed to extend over the first active region with the first gate insulating film sandwiched therebetween, and includes a first fully silicided gate electrode provided on the first active region and a first fully silicided gate line provided on the isolation region, and the first fully silicided gate pattern includes, along a gate width direction, a portion that has a first thickness and includes the first fully silicided gate electrode and portions that have a second thickness larger than the first thickness and are respectively disposed on both sides of the portion having the first thickness.

According to another aspect of the invention, the portion having the first thickness corresponds to the first fully silicided gate electrode, and the portion having the second thickness corresponds to the first fully silicided gate line.

According to another aspect of the invention, the semiconductor device further includes a first sidewall formed on a side face of the first fully silicided gate pattern; and a p-type impurity diffusion region formed in a portion of the first active region disposed on a side of the first sidewall, and the first sidewall has a smaller height on the side face of the portion having the first thickness than on the side face of the portion having the second thickness.

In a first structure of the semiconductor device according to one aspect of the invention, the semiconductor device further includes an n-type MIS transistor formed on a second active region surrounded with the isolation region in the semiconductor substrate, and the n-type MIS transistor includes a second gate insulating film formed on the second active region; and a second fully silicided gate electrode that is formed on the second gate insulating film to be adjacent to the first fully silicided gate electrode along the gate width direction and includes an extended portion of the first fully silicided gate line present on the second gate insulating film, and the second fully silicided gate electrode has a thickness the same as the second thickness.

In a second structure of the semiconductor device according to the aspect, the semiconductor device further includes an n-type MIS transistor formed on a second active region surrounded with the isolation region in the semiconductor substrate, and the n-type MIS transistor includes a second gate insulating film formed on the second active region; and a second fully silicided gate electrode that is obtained by fully siliciding a silicon film and is formed on the second gate insulating film to be adjacent to the first fully silicided gate electrode along the gate length direction, and the second fully silicided gate electrode has a thickness the same as the second thickness.

In the first or second structure of the semiconductor device according to the aspect of the invention, the semiconductor device further includes a second sidewall formed on a side face of the second fully silicided gate electrode; and a p-type impurity diffusion region formed in a portion of the second active region disposed on a side of the second sidewall, and the second sidewall has the same height as a portion of the first sidewall formed on the side face of the portion having the second thickness.

In a third structure of the semiconductor device according to the aspect of the invention, the semiconductor device further includes a second fully silicided gate pattern that is obtained by fully siliciding a silicon film and is formed on the isolation region in the semiconductor substrate; and a shared contact plug connected to the p-type impurity diffusion region and the second fully silicided gate pattern, and the second fully silicided gate pattern has a thickness the same as the second thickness.

In the third structure of the semiconductor device according to the aspect of the invention, the semiconductor device further includes a second sidewall formed on a side face of the second fully silicided gate pattern, and the second sidewall has the same height as a portion of the first sidewall formed on the side face of the portion having the second thickness.

In the third structure of the semiconductor device according to the aspect of the invention, the semiconductor device further includes an additional p-type MIS transistor formed on a second active region surrounded with the isolation region in the semiconductor substrate, and the second fully silicided gate pattern is formed to extend over the second active region with a second gate insulating film formed on the second active region sandwiched therebetween, and a portion of the second fully silicided gate pattern disposed on the second active region corresponds to a fully silicided gate electrode of the additional p-type MIS transistor.

The method for fabricating a semiconductor device according to an aspect of the invention includes the steps of (a) forming a first active region surrounded with an isolation region in a semiconductor substrate; (b) successively forming a gate insulating forming film, a silicon film and a protection film on the semiconductor substrate and patterning at least the silicon film and the protection film, whereby forming a first gate pattern silicon film patterned from the silicon film and a first protection film patterned from the protection film to extend over the first active region; (c) forming a first sidewall on a side face of the first gate pattern silicon film; (d) forming a first p-type impurity diffusion region in a portion of the first active region disposed on a side of the first sidewall through ion implantation of a p-type impurity by using the first sidewall as a mask; (e) exposing the first gate pattern silicon film by removing the first protection film after the step (d); (f) reducing a thickness of the first gate pattern silicon film on the first active region to be smaller than on the isolation region through etching using a resist mask pattern covering the isolation region and having a first opening pattern correspondingly to the first active region after the step (e); and (g) forming a metal film on the first gate pattern silicon film, and fully siliciding the first gate pattern silicon film by annealing the metal film, whereby forming a first fully silicided gate pattern including a first fully silicided gate electrode disposed on the first active region and a first fully silicided gate line disposed on the isolation region after the step (f).

In the method for fabricating a semiconductor device according to an aspect of the invention, the resist mask pattern covers the first p-type impurity diffusion region out of the first active region and has the first opening pattern correspondingly to the first gate pattern silicon film and the first sidewall in the step (f).

In a first method of the method for fabricating a semiconductor device according to an aspect of the invention, the step (a) includes a sub-step of forming a second active region surrounded with the isolation region in the semiconductor substrate, the first gate pattern silicon film and the first protection film are formed to extend over the second active region in the step (b), the step (d) includes a sub-step of forming an n-type impurity diffusion region in a portion of the second active region disposed on a side of the first sidewall through ion implantation of an n-type impurity by using the first sidewall as a mask, and the first fully silicided gate pattern including the first fully silicided gate electrode, the first fully silicided gate line and a second fully silicided gate electrode disposed on the second active region is formed in the step (g).

In a second method of the method for fabricating a semiconductor device according to the aspect of the invention, the step (a) includes a sub-step of forming a second active region surrounded with the isolation region in the semiconductor substrate, the step (b) includes a sub-step of forming a second gate pattern silicon film patterned from the silicon film and a second protection film patterned from the protection film to extend over the second active region and to be adjacent to and spaced from the first gate pattern silicon film and the first protection film along a gate length direction, the step (c) includes a sub-step of forming a second sidewall on a side face of the second gate pattern silicon film, the step (d) includes a sub-step of forming an n-type impurity diffusion region in a portion of the second active region disposed on a side of the second sidewall through ion implantation of an n-type impurity by using the second sidewall as a mask, the step (e) includes a sub-step of exposing the second gate pattern silicon film by removing the second protection film, and the step (g) includes a sub-step of forming the metal film on the second gate pattern silicon film and fully siliciding the second gate pattern silicon film by annealing the metal film, whereby forming a second fully silicided gate pattern including a second fully silicided gate electrode disposed on the second active region and a second fully silicided gate line disposed on the isolation region.

In a third method of the method for fabricating a semiconductor device according to the aspect of the invention, the step (b) includes a sub-step of forming a second gate pattern silicon film patterned from the silicon film and a second protection film patterned from the protection film on the isolation region to be adjacent to and spaced from the first gate pattern silicon film and the first protection film along a gate length direction, the step (c) includes a sub-step of forming a second sidewall on a side face of the second gate pattern silicon film, the step (e) includes a sub-step of exposing the second gate pattern silicon film by removing the second protection film, the step (g) includes a sub-step of forming the metal film on the second gate pattern silicon film and fully siliciding the second gate pattern silicon film by annealing the metal film, whereby forming a second fully silicided gate pattern, and the method further includes, after the step (g), a step (h) of forming a shared contact connected to the p-type impurity diffusion region and the second fully silicided gate pattern.

In the third method of the method for fabricating a semiconductor device according to the aspect of the invention, the step (a) includes a sub-step of forming a second active region surrounded with the isolation region in the semiconductor substrate, the step (d) includes a sub-step of forming a second p-type impurity diffusion region in a portion of the second active region disposed on a side of the second sidewall through ion implantation of a p-type impurity by using the second sidewall as a mask, a thickness of the second gate pattern silicon film is reduced on the second active region to be smaller than on the isolation region through etching using the resist mask pattern having a second opening pattern correspondingly to the second active region in the step (f), and the second fully silicided gate pattern including a second fully silicided gate line disposed on the isolation region and a second fully silicided gate electrode disposed on the second active region is formed in the step (g).

As described so far, according to the semiconductor device and the fabrication method for the same of this invention, with respect to a semiconductor device employing the fully silicided gate process with a small gate line width, a semiconductor device including a gate line with low interconnect resistance and a method for fabricating the same can be realized.

### BRIEF DESCRIPTION OF THE DRAWINGS

FIGS. 1A, 1B and 1C are diagrams for explaining the structure of a semiconductor device according to Embodiment 1 of the invention, and specifically, FIG. 1A is a plan view thereof, FIG. 1B is a cross-sectional view thereof taken on line Ib-Ib of FIG. 1A and FIG. 1C is a cross-sectional view thereof taken on line Ic-Ic of FIG. 1A.

FIGS. 2A, 2B, 2C and 2D are cross-sectional views for showing procedures in a method for fabricating a semiconductor device according to Embodiment 1 of the invention.

FIGS. 3A, 3B, 3C and 3D are cross-sectional views for showing other procedures in the method for fabricating a semiconductor device of Embodiment 1 of the invention.

FIGS. 4A, 4B and 4C are plan views of a resist mask pattern used in the method for fabricating a semiconductor device of Embodiment 1 of the invention, a resist mask pattern according to a modification of Embodiment 1 and a resist mask pattern according to a comparative example, respectively.

FIGS. 5A, 5B, 5C and 5D are cross-sectional views for showing other procedures in the method for fabricating a semiconductor device of Embodiment 1 of the invention.

FIGS. 6A, 6B, 6C and 6D are cross-sectional views for showing other procedures in the method for fabricating a semiconductor device of Embodiment 1 of the invention performed by using the resist mask pattern of the modification shown in FIG. 4B.

FIGS. 7A and 7B are diagrams for explaining the structure of a semiconductor device according to Embodiment 2 of the invention, and specifically, FIG. 7A is a plan view thereof and FIG. 7B is a cross-sectional view thereof taken on line VIIb-VIIb of FIG. 7A.

FIGS. 8A, 8B, 8C and 8D are cross-sectional views for showing procedures in a method for fabricating a semiconductor device according to Embodiment 2 of the invention.

FIGS. 9A, 9B, 9C and 9D are cross-sectional views for showing other procedures in the method for fabricating a semiconductor device of Embodiment 2 of the invention.

FIG. 10 is a plan view of a resist mask pattern used in the method for fabricating a semiconductor device of Embodiment 2 of the invention.

FIG. 11 is a plan view of a resist mask pattern mentioned as a comparative example in the method for fabricating a semiconductor device of Embodiment 2 of the invention.

FIGS. 12A, 12B, 12C and 12D are cross-sectional views for showing other procedures in the method for fabricating a semiconductor device of Embodiment 2 of the invention.

### DETAILED DESCRIPTION OF THE INVENTION

### Embodiment 1

A semiconductor device and a method for fabricating the same according to Embodiment 1 of the invention will now be described with reference to the accompanying drawings.

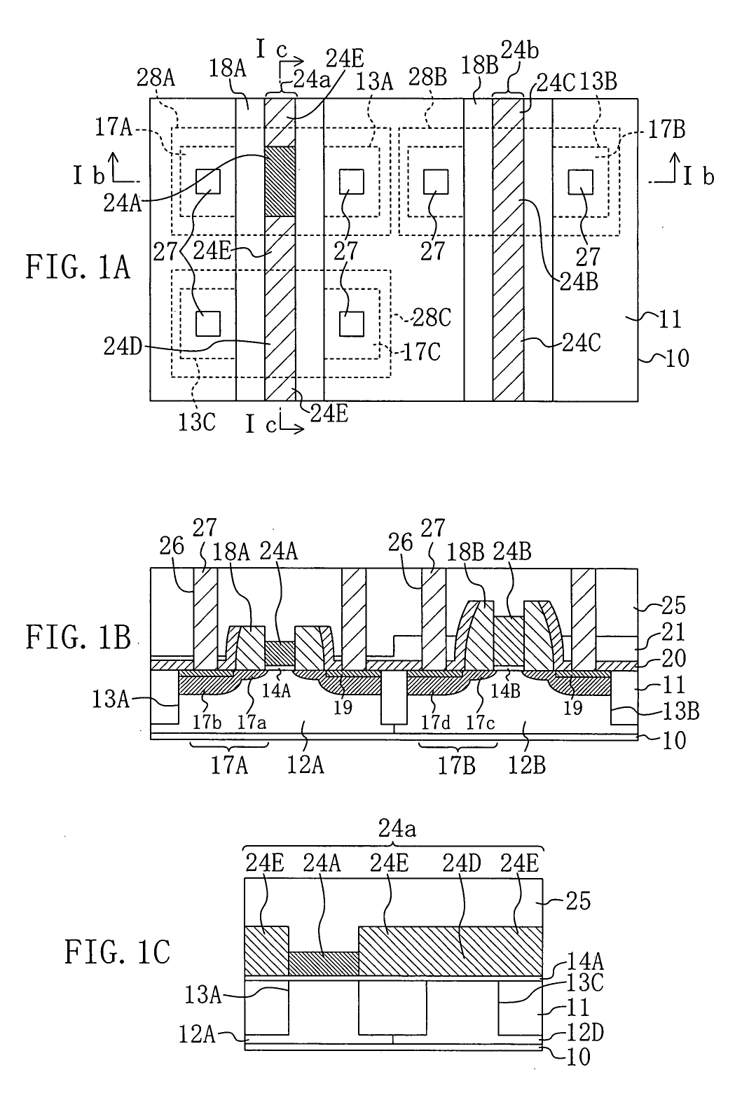

First, the structure of the semiconductor device of Embodiment 1 will be described with reference to FIGS. 1A through 1C.

FIGS. 1A through 1C are diagrams for explaining the structure of the semiconductor device of Embodiment 1 of the invention, and specifically, FIG. 1A is a plan view thereof, FIG. 1B is a cross-sectional view thereof taken on line Ib-Ib of FIG. 1A and FIG. 1C is a cross-sectional view thereof taken on line Ic-Ic of FIG. 1A. It is noted that part of the structure correspondingly shown in FIGS. 1B and 1C is omitted in FIG. 1A for convenience of the explanation.

As shown in the plan view of FIG. 1A, a first active region 13A included in a p-type MIS transistor forming region 28A, a second active region 13B included in an n-type MIS transistor forming region 28B and a third active region 13C included in an n-type MIS transistor forming region 28C are formed in a semiconductor substrate 10 of, for example, silicon so as to be surrounded with an isolation region 11.

A first fully silicided gate pattern 24a obtained by fully siliciding a gate pattern silicon film is formed above the first active region 13A, the third active region 13C and the isolation region 11 so as to extend over the first active region 13A and the third active region 13C along the gate width direction. The first fully silicided gate pattern 24a includes a first fully silicided gate electrode 24A made of a fully silicided material of, for example, Ni₂Si, Ni₃Si or Ni₃₁Si₁₂ and included in a p-type MIS transistor formed on the first active region 13A, a third fully silicided gate electrode 24D made of a fully silicided material of, for example, NiSi and included in an n-type MIS transistor formed on the third active region 13C and a first fully silicided gate line 24E made of the fully silicided material of, for example, NiSi. The first fully silicided gate electrode 24A, the third fully silicided gate electrode 24D and the first fully silicided gate line 24E are continuously and integrally formed so as to build a dual gate structure.

A second fully silicided gate pattern 24b obtained by fully siliciding a gate pattern silicon film is formed above the second active region 13B and the isolation region 11 so as to be adjacent to and spaced from the first fully silicided gate pattern 24a. The second fully silicided gate pattern 24b includes a second fully silicided gate electrode 24B made of a fully silicided material of, for example, NiSi and included in an n-type MIS transistor formed on the second active region 13B and a second fully silicided gate line 24C made of a fully silicided material of, for example, NiSi and continuously and integrally formed with the second fully silicided gate electrode 24B.

A first sidewall 18A made of, for example, a silicon nitride film is formed on the side face of the first fully silicided gate pattern 24a, and a second sidewall 18B made of, for example, a silicon nitride film is formed on the side face of the second fully silicided gate pattern 24b. A p-type first source/drain region 17A is formed in a portion of the first active region 13A disposed on a side of and below the first sidewall 18A, an n-type second source/drain region 17B is formed in a portion of the second active region 13B disposed on a side of and below the second sidewall 18B, and an n-type third source/drain region 17C is formed in a portion of the third active region 13C disposed on a side of and below the first sidewall 18A. A silicide layer not shown (but shown with a reference numeral of 19 in FIG. 1B mentioned below) is formed in surface portions of the first through third source/drain regions 17A through 17C, and contact plugs 27 connected to the first through third source/drain regions 17A through 17C through this silicide layer are formed so as to penetrate an underlying protection film not shown (but shown with a reference numeral of 20 in FIG. 1B mentioned below) and first and second interlayer insulating films (shown with reference numerals of 21 and 25 in FIG. 1B mentioned below).

In the cross-sectional view of FIG. 1B, the isolation region 11 made of shallow trench isolation, the first active region 13A surrounded with the isolation region 11 and including an n-type well 12A, and the second active region 13B surrounded with the isolation region 11 and including a p-type well 12B are formed in the semiconductor substrate 10. The first fully silicided gate electrode 24A included in the first fully silicided gate pattern 24a is formed above the first active region 13A with a first gate insulating film 14A made of, for example, a silicon oxide film sandwiched therebetween.

Also, the second fully silicided gate electrode 24B included in the second fully silicided gate pattern 24b is formed above the second active region 13B with a second gate insulating film 14B made of, for example, a silicon oxide film sandwiched therebetween.

A p-type source/drain region (a p-type extension region or a p-type LDD region) 17a with a comparatively small junction depth is formed in an upper portion of the first active region 13A disposed on a side of and below the first fully silicided gate electrode 24A. An n-type source/drain region (an n-type extension region or an n-type LDD region) 17c with a comparatively small junction depth is formed in an upper portion of the second active region 13B disposed on a side of and below the second fully silicided gate electrode 24B. Furthermore, the first sidewall 18A is formed on the side face of the first fully silicided gate electrode 24A and the second sidewall 18B is formed on the side face of the second fully silicided gate electrode 24B. At this point, the height of the first sidewall 18A from the top face of the first active region 13A is smaller than the height of the second sidewall 18B from the top face of the second active region 13B as shown in FIG. 1B.

A p-type source/drain region 17b with a comparatively large junction depth is formed in an upper portion of the first active region 13A disposed on a side of and below the first sidewall 18A, and an n-type source/drain region 17d with a comparatively large junction depth is formed in an upper portion of the second active region 13B disposed on a side of and below the second sidewall 18B. The p-type source/drain region 17a with a comparatively small junction depth and the p-type source/drain region 17b with a comparatively large junction depth together form the p-type first source/drain region 17A, and the n-type source/drain region 17c with a comparatively small junction depth and the n-type source/drain region 17d with a comparatively large junction depth together form the n-type second source/drain region 17B.

The silicide layer 19 is formed in a portion of the first source/drain region 17A disposed on the p-type source/drain region 17b and on a side of and below the first sidewall 18A and in a portion of the second source/drain region 17B disposed on the n-type source/drain region 17d and on a side of and below the second sidewall 18B. The underlying protection film 20 made of, for example, a silicon nitride film is formed on the isolation region 11 and the silicide layer 19 and on the side face of the first fully silicided gate pattern 24a (see FIG. 1A) including the first fully silicided gate electrode 24A and on the side face of the second fully silicided gate pattern 24b (see FIG. 1A) including the second fully silicided gate electrode 24B. It is noted that the underlying protection film 20 is formed above the side face of the first fully silicided gate pattern 24a with the first sidewall 18A sandwiched therebetween and that the underlying protection film 20 is formed above the side face of the second fully silicided gate pattern 24b with the second sidewall 18B sandwiched therebetween. Accordingly, the underlying protection film 20 is not formed on the top faces of the first fully silicided gate pattern 24a and the second fully silicided gate pattern 24b and on the top faces of the first sidewall 18A and the second sidewall 18B.

The first interlayer insulating film 21 and the second interlayer insulating film 25 each made of, for example, a silicon oxide film are successively formed on the underlying protection film 20, and the first interlayer insulating film 21 is not formed but the second interlayer insulating film 25 alone is formed on the first sidewall 18A and the first fully silicided gate pattern 24a and on the second sidewall 18B and the second fully silicided gate pattern 24b. In the second interlayer insulating film 25, the first interlayer insulating film 21 and the underlying protection film 20, the contact plug 27 connected to the first source/drain region 17A through the silicide layer 19 and made of a conducting material such as tungsten filled in a contact hole 26 and the contact plug 27 connected to the second source/drain region 17B through the silicide layer 19 and made of a conducting material such as tungsten filled in a contact hole 26 are formed. It is noted that the structure of the n-type MIS transistor formed on the third active region 13C shown in FIG. 1A is the same as that of the n-type MIS transistor shown on the right hand side in FIG. 1B and hence the description is omitted.

Furthermore, in the cross-sectional view of FIG. 1C, the cross-section of the first fully silicided gate pattern 24a along the gate width direction is shown. As shown in FIG. 1C, the first fully silicided gate pattern 24a includes the first fully silicided gate electrode 24A included in the p-type MIS transistor provided on the first active region 13A and made of the fully silicided material of, for example, Ni₂Si, Ni₃Si or Ni₃₁Si₁₂, the first fully silicided gate line 24E provided on the isolation region 11 and made of the fully silicided material of, for example, NiSi, and the third fully silicided gate electrode 24D included in the n-type MIS transistor disposed on the third active region 13C including the p-type well 12D and made of the fully silicided material of, for example, NiSi.

In the semiconductor device according to Embodiment 1 of the invention having the aforementioned structure, the fully silicided material of, for example Ni₂Si, Ni₃Si or Ni₃₁Si₁₂ having high interconnect resistance is used as a material for merely the first fully silicided gate electrode 24A provided on the first active region 13A where the p-type MIS transistor is formed, and the first fully silicided gate line 24E provided on the isolation region 11 and the third fully silicided gate electrode 24D provided on the third active region 13C are made of the fully silicided material of, for example, NiSi having low interconnect resistance. Therefore, the interconnect resistance can be lowered. Also, since the fully silicided material of, for example, NiSi having low interconnect resistance is used as the material for the whole second fully silicided gate pattern 24b, the interconnect resistance can be lowered.

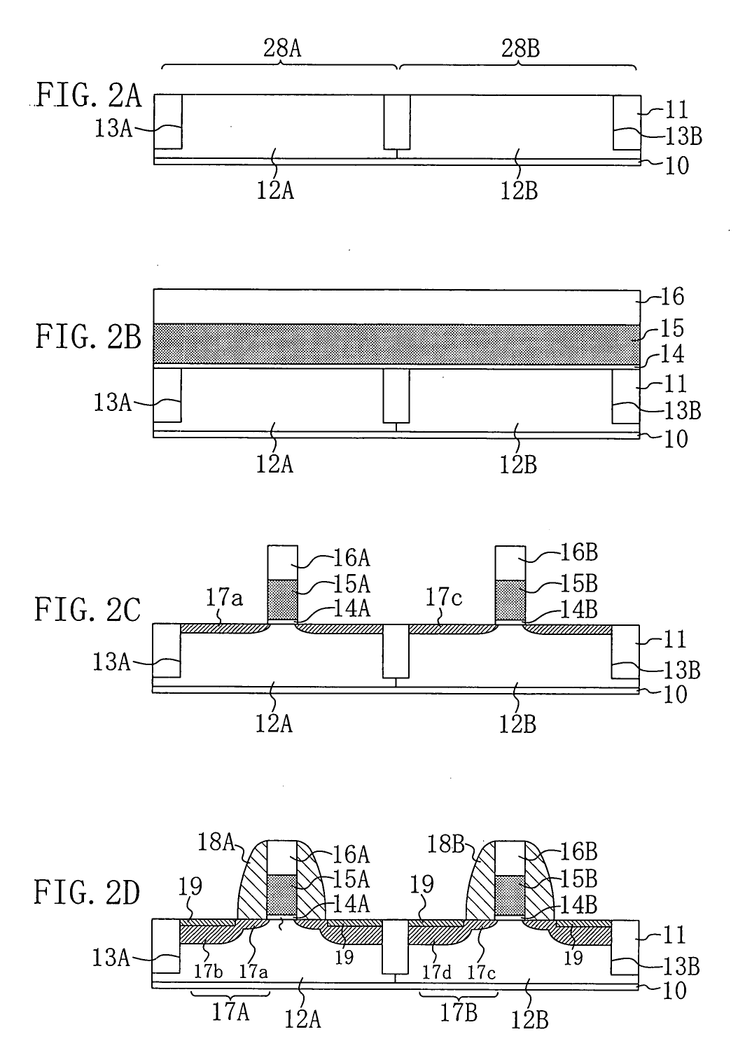

Now, a method for fabricating a semiconductor device according to Embodiment 1 of the invention will be described with reference to FIGS. 2A through 2D, 3A through 3D, 4A through 4C, 5A through 5D and 6A through 6D. In the following description, procedures performed until the cross-sectional structure of FIG. 1B is attained will be principally exemplarily described, and while appropriately referring to FIG. 1A described above, procedures for forming the n-type MIS transistor provided on the third active region 13C (see FIG. 1A) not included in the cross-sectional structure will be also described.

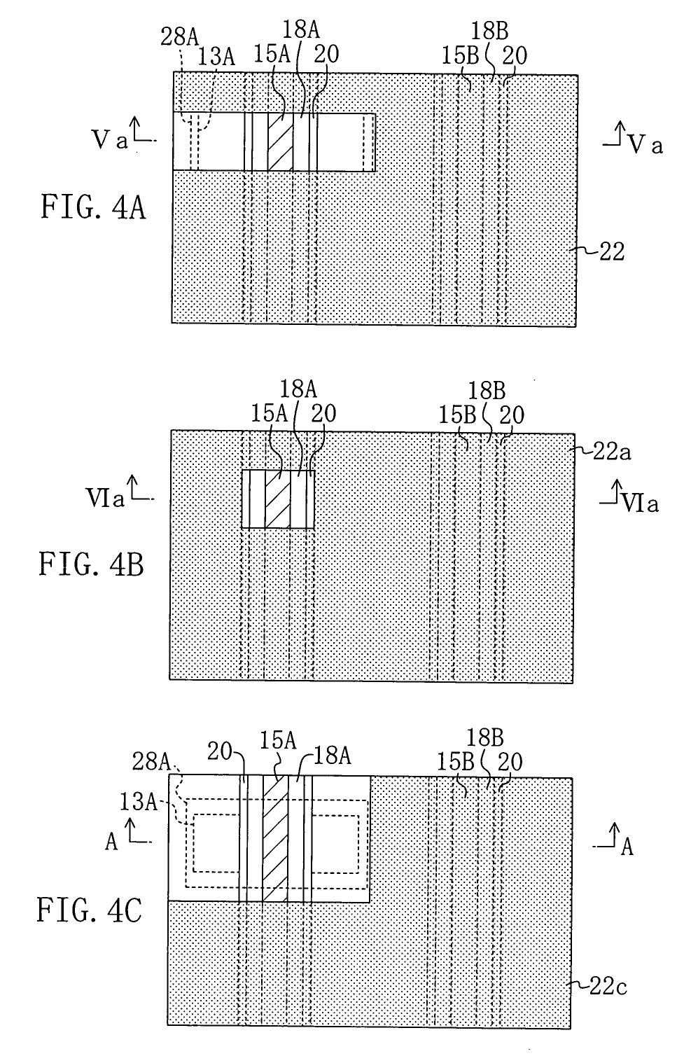

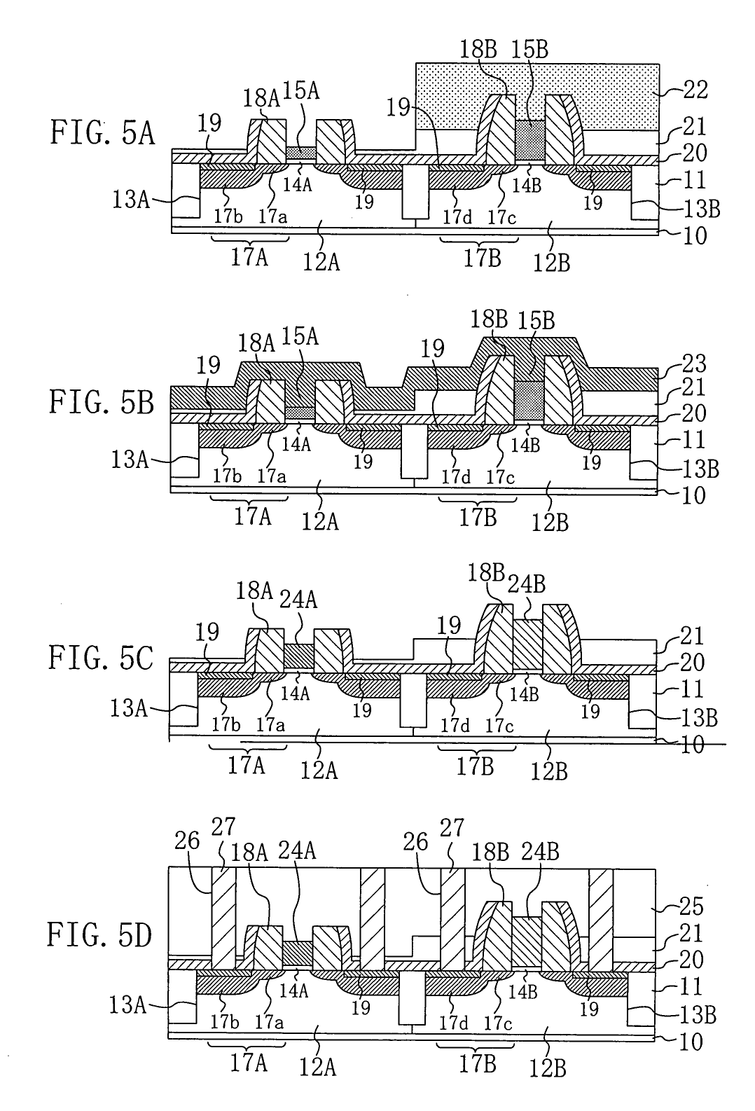

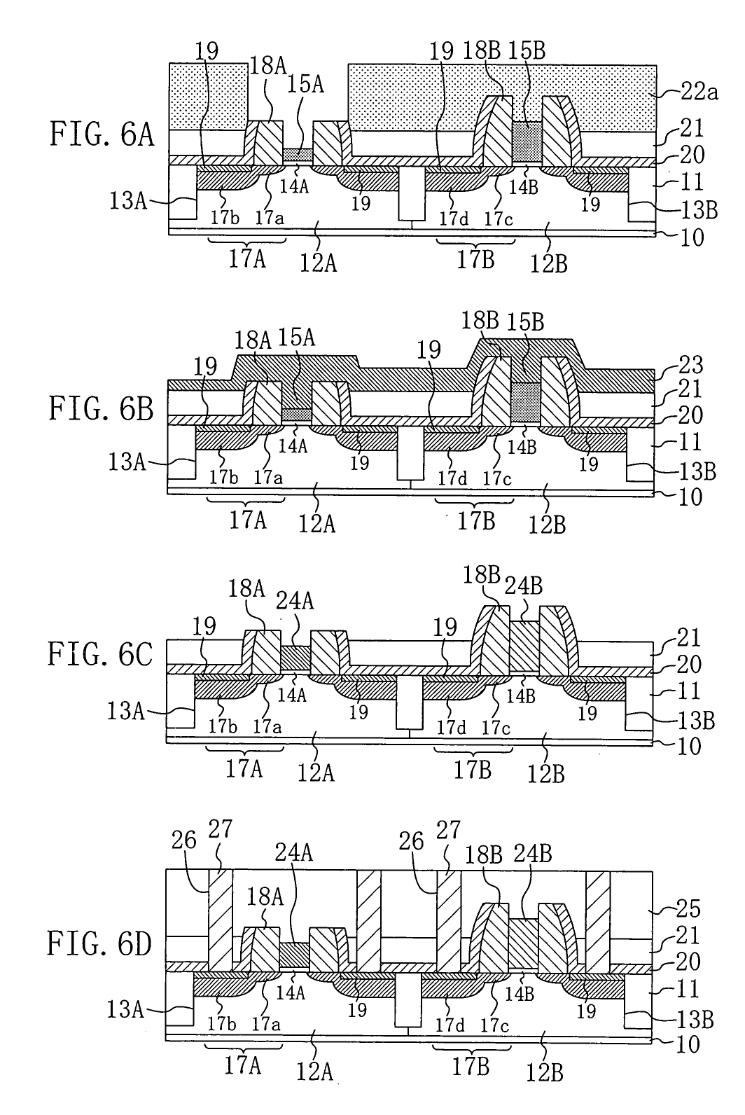

FIGS. 2A through 2D, 3A through 3D, 4A through 4C, 5A through 5D and 6A through 6D are diagrams for explaining the method for fabricating a semiconductor device of Embodiment 1 of the invention, and FIGS. 2A through 2D, 3A through 3D, 5A through 5D and 6A through 6D successively show fabrication procedures in cross-sectional views taken on line Ib-Ib of FIG. 1A, namely, the cross-sectional view of FIG. 1B, and FIGS. 4A through 4C are plan views of an opening pattern of a resist mask pattern used in the procedure of FIG. 5A, an opening pattern of a modification of the resist mask pattern and an opening pattern of a conventional mask pattern mentioned as a comparative example. Moreover, FIGS. 6A through 6D are cross-sectional views for showing procedures performed by using the resist mask pattern of the modification and corresponding to the procedures shown in FIGS. 5A through 5D.

First, as shown in FIG. 2A, an isolation region 11 for electrically isolating a device is formed in a surface portion of a semiconductor substrate 10 of, for example, silicon by an STI (shallow trench isolation) method or the like. Next, by photolithography and ion implantation, an n-type well 12A is formed by implanting an n-type impurity (such as phosphorus) in a p-type MIS transistor forming region 28A of the semiconductor substrate 10, and a p-type well 12B is formed by implanting a p-type impurity (such as boron) in an n-type MIS transistor forming region 28B of the semiconductor substrate 10. Thus, a first active region 13A surrounded with the isolation region 11 and including the n-type well 12A and a second active region 13B surrounded with the isolation region 11 and including the p-type well 12B are formed in the semiconductor substrate 10. Although not shown in the drawing, a third active region 13C surrounded with the isolation region 11 and including a p-type well 12D similarly to the second active region 13B is formed in an n-type MIS transistor forming region 28C of the semiconductor substrate 10.

Next, as shown in FIG. 2B, after forming a gate insulating forming film 14 with a thickness of 2 nm made of, for example, a silicon oxide film over the semiconductor substrate 10, a silicon film 15 with a thickness of 100 nm made of, for example, polysilicon is deposited on the gate insulating forming film 14 by CVD (chemical vapor deposition) or the like. Subsequently, a protection film 16 with a thickness of 70 nm made of, for example, a silicon oxide film is formed on the silicon film 15 by the CVD or the like.

Next, as shown in FIG. 2C, the gate insulating forming film 14, the silicon film 15 and the protection film 16 are selectively etched by the photolithography and dry etching. In this selective etching, the gate insulating forming film 14, the silicon film 15 and the protection film 16 are patterned so as to remain in first and second fully silicided gate patterns 24a and 24b shown in FIG. 1A to be formed later. In this manner, a first gate insulating film 14A, a first gate electrode silicon film 15A and a first protection film 16A all patterned by the etching are formed on the first active region 13A, and a second gate insulating film 14B, a second gate electrode silicon film 15B and a second protection film 16B all patterned by the etching are formed on the second active region 13B. Although not shown in the drawing, at this point simultaneously with the formation of the first gate electrode silicon film 15A, a first gate line silicon film continuous to the first gate electrode silicon film 15A and a third gate electrode silicon film continuous to the first gate electrode silicon film 15A and the first gate line silicon film are formed respectively on the isolation region 11 and the third active region 13C, and simultaneously with the formation of the second gate electrode silicon film 15B, a second gate line silicon film continuous to the second gate electrode silicon film 15B is formed on the isolation region 11. In this manner, a first gate pattern silicon film integrally including the first gate electrode silicon film 15A, the first gate line silicon film and the third gate electrode silicon film is formed in a region for the first fully silicided gate pattern 24a, and a second gate pattern silicon film integrally including the second gate electrode silicon film 15B and the second gate line silicon film is formed in a region for the second fully silicided gate pattern 24b.

Subsequently, a resist mask pattern (not shown) for covering the second active region 13B and the third active region 13C not shown (see FIG. 1A) is formed, and a p-type impurity is ion implanted by using the first gate electrode silicon film 15A and the first protection film 16A as a mask, so as to form p-type source/drain regions (p-type extension regions or p-type LDD regions) 17a with a comparatively small junction depth in portions of the first active region 13A disposed on both sides of and below the first gate electrode silicon film 15A. Similarly, a resist mask pattern (not shown) for covering the first active region 13A is formed, and an n-type impurity is ion implanted by using the second gate electrode silicon film 15B and the second protection film 16B as a mask, so as to form n-type source/drain regions (n-type extension regions or n-type LDD regions) 17c with a comparatively small junction depth in portions of the second active region 13B disposed on both sides of and below the second gate electrode silicon film 15B. At this point, simultaneously with the formation of the n-type source/drain regions 17c, n-type source/drain regions (n-type extension regions or n-type LDD regions) with a comparatively small junction depth are formed in portions of the third active region 13C disposed on both sides of and below the third gate electrode silicon film.

Next, as shown in FIG. 2D, after depositing, for example, a silicon nitride film with a thickness of 50 nm over the semiconductor substrate 10 by the CVD or the like, the deposited silicon nitride film is subjected to anisotropic etching, so as to form a first sidewall 18A on the side faces of the first gate electrode silicon film 15A and the first protection film 16A and to form a second sidewall 18B on the side faces of the second gate electrode silicon film 15B and the second protection film 16B. At this point, the first sidewall 18A is simultaneously formed also on the side faces of the first gate line silicon film and the third gate electrode silicon film continuous to the first gate electrode silicon film 15A, and the second sidewall 18B is simultaneously formed also on the side face of the second gate line silicon film continuous to the second gate electrode silicon film 15B.

Subsequently, a resist mask pattern (not shown) for covering the second active region 13B and the third active region 13C (see FIG. 1A) is formed by the photolithography, and a p-type impurity is ion implanted in the first active region 13A by using the first sidewall 18A as a mask, so as to form p-type source/drain regions 17b with a comparatively large junction depth in portions of the first active region 13A disposed on outer sides of and below the first sidewall 18A. Also, a resist mask pattern (not shown) for covering the first active region 13A is formed, and an n-type impurity is ion implanted in the second active region 13B by using the second sidewall 18B as a mask, so as to form n-type source/drain regions 17d with a comparatively large junction depth in portions of the second active region 13B disposed on outer sides of and below the second sidewall 18B. At this point, n-type source/drain regions with a large junction depth are also formed in portions of the third active region 13C disposed on outer sides of and below the second sidewall 18A. Thereafter, annealing is performed at a temperature of 1000° C. or more, so as to electrically activate the ion implanted impurities. In this manner, first source/drain regions 17A each including the p-type source/drain region 17a with a comparatively small junction depth and the p-type source/drain region 17b with a comparatively large junction depth are formed in the first active region 13A, and second source/drain regions 17B each including the n-type source/drain region 17c with a comparatively small junction depth and the n-type source/drain region 17d with a comparatively large junction depth are formed in the second active region 13B. Similarly, third source/drain regions 17C each including the n-type source/drain region with a comparatively small junction depth and the n-type source/drain region with a comparatively large junction depth are formed in the third active region 13C.

Subsequently, after removing nature oxide from the surfaces of the first source/drain regions 17A, the second source/drain regions 17B and the third source/drain regions 17C (see FIG. 1C), a metal film (not shown) made of, for example, nickel with a thickness of 11 nm is deposited on the semiconductor substrate 10 by spattering or the like. Thereafter, the semiconductor substrate 10 is subjected to first RTA (rapid thermal annealing) at 320° C. in a nitrogen atmosphere for causing a reaction between silicon and the metal film, so as to nickel silicide surface portions of the first source/drain regions 17A, the second source/drain regions 17B and the third source/drain regions 17C. Subsequently, the resultant semiconductor substrate 10 is immersed in an etchant made of a mixed solution of sulfuric acid and hydrogen peroxide water, so as to remove unreacted portions of the metal film remaining on the isolation region 11, the first protection film 16A, the second protection film 16B, the first sidewall 18A, the second sidewall 18B and the like. Thereafter, the semiconductor substrate 10 is subjected to second RTA at a higher temperature (of, for example, 550° C.) than in the first RTA. Thus, a silicide layer 19 with low resistance is formed in the surface portions of the first source/drain regions 17A, the second source/drain regions 17B and the third source/drain regions 17C.

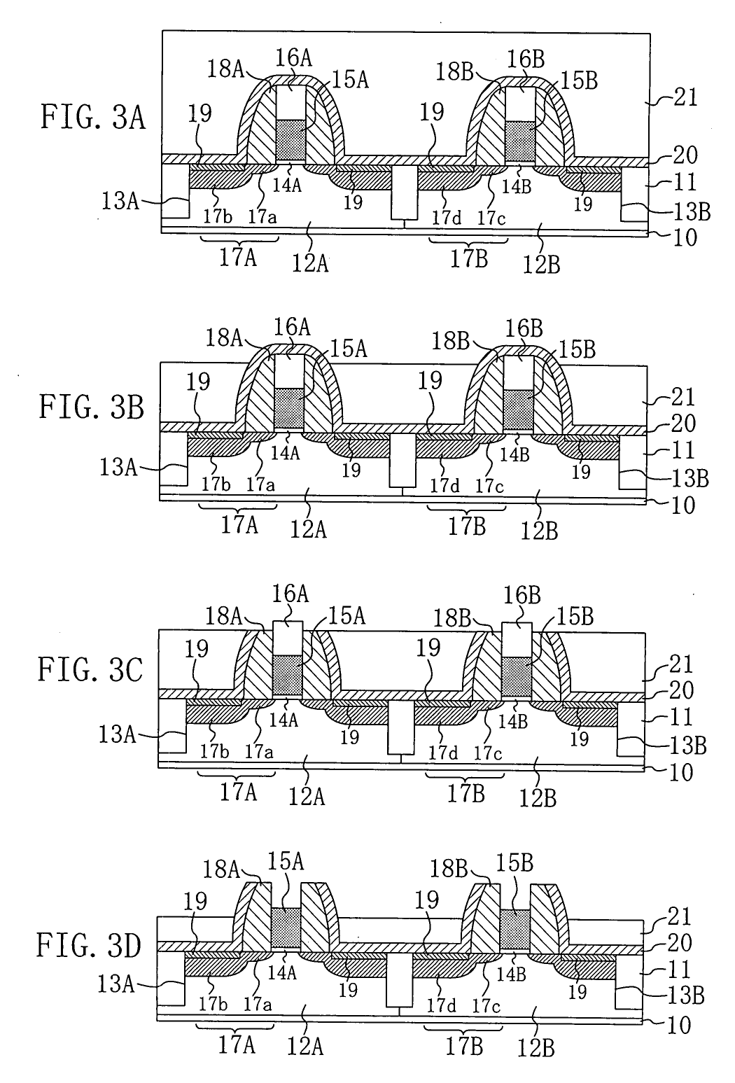

Next, as shown in FIG. 3A, an underlying protection film 20 with a thickness of 20 nm made of, for example, a silicon nitride film is deposited over the semiconductor substrate 10 by the CVD or the like, and a first interlayer insulating film 21 made of, for example, a silicon oxide film is formed on the deposited underlying protection film 20. Subsequently, the surface of the first interlayer insulating film 21 is planarized by CMP (chemical mechanical polishing).

Then, as shown in FIG. 3B, the first interlayer insulating film 21 is etched by dry etching or wet etching performed under etching conditions set for attaining large selectivity against a silicon nitride film until portions of the underlying protection film 20 formed on the first protection film 16A and the second protection film 16B are exposed.

Next, as shown in FIG. 3C, the first protection film 16A and the second protection film 16B are exposed by removing the portions of the underlying protection film 20 formed thereon by the dry etching or wet etching performed under etching conditions set for attaining large selectivity against a silicon oxide film.

Subsequently, as shown in FIG. 3D, the top faces of the first gate electrode silicon film 15A and the second gate electrode silicon film 15B are exposed by removing portions of the first protection film 16A and the second protection film 16B formed thereon by the dry etching or wet etching performed under etching conditions set for attaining large selectivity against a silicon nitride film and a polysilicon film. In exposing the top face of the first gate electrode silicon film 15A, the top faces of the first gate line silicon film and the third gate electrode silicon film continuous to the first gate electrode silicon film 15A are simultaneously exposed, and in exposing the top face of the second gate electrode silicon film 15B, the top face of the second gate line silicon film continuous to the second gate electrode silicon film 15B is simultaneously exposed. Furthermore, in removing the first protection film 16A and the second protection film 16B, an upper portion of the first interlayer insulating film 21 is simultaneously removed by the etching.

Next, as shown in FIGS. 4A and 5A (whereas FIG. 5A is a cross-sectional view taken on line Va-Va of FIG. 4A), a resist mask pattern 22 covering the second active region 13B, the third active region 13C and the isolation region 11 and having an opening pattern above the first active region 13A of the p-type MIS transistor is formed over the semiconductor substrate 10 by the photolithography. At this point, in the opening pattern of the resist mask pattern 22, the width along the gate length direction may be larger than the width of the first active region 13A along the gate length direction and the width along the gate width direction is preferably equivalent to the width of the first active region 13A along the gate width direction.

Subsequently, the first gate electrode silicon film 15A is etched by the dry etching excluding a portion thereof covered by the resist mask pattern 22 so as to reduce its thickness to approximately 40 nm. At this point, upper portions of the underlying protection film 20, the first sidewall 18A and the first interlayer insulating film 21 exposed from the resist mask pattern 22 are also simultaneously removed by the etching. In this procedure, since the resist mask pattern 22 exposing an area merely above the first active region 13A of the p-type MIS transistor is used, a first fully silicided gate electrode 24A provided on the first active region 13A alone can be made of a fully silicided material of Ni₂Si, Ni₃Si or Ni₃₁Si₁₂ as described below, and thus, the interconnect resistance can be lowered. In the conventional technique, a resist mask pattern 22c having an opening pattern for exposing not only an area above the first active region 13A of the p-type MIS transistor but also an area above the isolation region 11 formed on the side of the adjacent n-type MIS transistor forming region is used as shown in the comparative example of FIG. 4C. The opening pattern of this resist mask pattern 22c has a larger width along the gate width direction than the width of the first active region 13A along the gate width direction and is formed to expose also the area above the isolation region, and therefore, the gate line silicon film is thinned by the etching, and when a gate line made of a silicided material of, for example, Ni₂Si, Ni₃Si or Ni₃₁Si₁₂ is formed, the interconnect resistance is unavoidably high. On the contrary, when the resist mask pattern 22 of this embodiment is used in this procedure, the interconnect resistance can be obviously lowered. In the plan view of FIG. 4C, the conventional resist pattern 22c is applied to the structure of this embodiment, and the cross-sectional structure taken on line A-A is the same as the cross-sectional structure taken on line Va-Va of FIG. 4A. Also, the application of the resist pattern 22 shown in FIGS. 4A and 5A is herein described and the following procedures will be described with reference to FIGS. 5B through 5D, and as a modification, a resist pattern 22a shown in FIGS. 4B and 6A described in detail below may be used instead with the following procedures performed as shown in FIGS. 5B through 5D.

Next, as shown in FIG. 5B, a metal film 23 with a thickness of 100 nm made of, for example, nickel is deposited on the first interlayer insulating film 21 by, for example, the spattering, so as to cover the first gate electrode silicon film 15A, the second gate electrode silicon film 15B, the third gate electrode silicon film and the first gate line silicon film (not shown) continuous to the first gate electrode silicon film 15A and the second gate line silicon film (not shown) continuous to the second gate electrode silicon film 15B.

Then, as shown in FIG. 5C, the semiconductor substrate 10 is subjected to first RTA in a nitrogen atmosphere at a temperature of 380° C., so as to silicide the first gate electrode silicon film 15A and the second gate electrode silicon film 15B and to silicide the third gate electrode silicon film, the first gate line silicon film and the second gate line silicon film. Subsequently, the resultant semiconductor substrate 10 is immersed in an etchant made of a mixed solution of sulfuric acid and hydrogen peroxide water, so as to remove unreacted portions of the metal film remaining on the first interlayer insulating film 21, the underlying protection film 20, the first sidewall 18A, the second sidewall 18B and the like, and then, the semiconductor substrate 10 is subjected to second RTA at a higher temperature (of, for example, 500° C.) than in the first RTA. Thus, the first gate electrode silicon film 15A and the second gate electrode silicon film 15B are fully silicided, so as to form a first fully silicided gate electrode 24A made of a fully silicided material of, for example, Ni₂Si, Ni₃Si or Ni₃₁Si₁₂, a second fully silicided gate electrode 24B made of a fully silicided material of NiSi, and the third gate electrode silicon film, the first gate line silicon film and the second gate line silicon film are fully silicided, so as to form a third fully silicided gate electrode 24D, a first fully silicided gate line 24E and a second fully silicided gate line 24C (see FIG. 1A) each made of a fully silicided material of, for example, NiSi.

Next, as shown in FIG. 5D, a second interlayer insulating film 25 is deposited over the semiconductor substrate 10 by the CVD or the like, and the surface of the second interlayer insulating film 25 is planarized by the CMP. Subsequently, a resist mask pattern (not shown) is formed on the second interlayer insulating film 25, so as to form contact holes 26 for exposing portions of the silicide layer 19 formed in the surface portions of the first through third source/drain regions 17A through 17C (see also FIG. 1A) by the dry etching. At this point, two-step etching in which the etching is once stopped when the underlying protection film 20 of a silicon nitride film is exposed may be performed so as to reduce over etching of the silicide layer 19.

Subsequently, titanium and titanium nitride are successively deposited respectively as an adhesive layer for tungsten and a barrier metal layer within the contact holes 26 by the spattering or the CVD, and tungsten is deposited thereon by the CVD. Then, the deposited tungsten is subjected to the CMP so as to remove portions of the tungsten deposited outside the contact holes 26. Thus, contact plugs 27 connected to the first source/drain regions 17A through 17C through the silicide layer 19 are formed.

As described so far, according to the method for fabricating a semiconductor device of this embodiment, in the first fully silicided gate pattern 24a, merely the first fully silicided gate electrode 24A provided on the first active region 13A included in the p-type MIS transistor forming region is made of the fully silicided material of, for example, Ni₂Si, Ni₃Si or Ni₃₁Si₁₂ with high resistance, and the first fully silicided gate line 24E provided on the isolation region 11 and the third fully silicided gate electrode 24D provided on the third active region 13C, namely, the interconnect and the electrode provided outside the p-type MIS transistor forming region, are made of the fully silicided material of, for example, NiSi with low resistance. Therefore, the gate line resistance can be lowered. Furthermore, in the second fully silicided gate pattern 24b, the second fully silicided gate electrode 24B provided on the second active region 13B and the second fully silicided gate line 24C provided on the isolation region 11 are made of the fully silicided material of, for example, NiSi with low resistance, and hence, the gate line resistance can be lowered.

As a modification of the method for fabricating a semiconductor device of this embodiment described above, the use of the resist pattern mask 22a shown in FIGS. 4B and 6A instead of the resist pattern mask 22 shown in FIGS. 4A and 5A will now be described. In this modification, description similar to that given with respect to FIGS. 4A and 5A through 5D is omitted.

As shown in FIGS. 4B and 6A (whereas FIG. 6A is a cross-sectional view taken on line VIa-VIa of FIG. 4B), the method for fabricating a semiconductor device of this modification is characterized by the use of the resist mask pattern 22a having an opening pattern correspondingly to the first gate electrode silicon film 15A provided on the first active region 13A, and the first sidewall 18A and the underlying protection film 20 formed on the side face of the first gate electrode silicon film 15A. When this resist mask pattern 22a is used, an upper portion of the first interlayer insulating film 21 provided in the p-type MIS transistor forming region, which is removed in using the resist mask pattern 22, is not removed, and therefore, the first interlayer insulating film 21 can be prevented from being thinned. Thereafter, the procedures described with reference to FIGS. 5A through 5C are similarly performed as shown in FIGS. 6A through 6C. In this manner, according to the method for fabricating a semiconductor device of the modification of this embodiment, not only the gate line resistance can be lowered but also the first interlayer insulating film 21 can be prevented from being thinned. Therefore, in forming the contact plugs 27, occurrence of a junction leakage current derived from punch through to the semiconductor substrate 10 can be suppressed.

In this embodiment, although the length along the gate width direction of the opening patterns of the resist mask patterns 22 and 22a shown in FIGS. 4A, 4B, 5A and 6A preferably accords with the width along the gate width direction of the first source/drain region 17A, the length of the opening pattern is not limited to this but may be increased along the gate width direction as far as the first fully silicided gate electrode 24A of the p-type MIS transistor formed on the first active region 13A can be made of the fully silicided material of, for example, Ni₂Si, Ni₃Si or Ni₃₁Si₁₂ as described above.

### Embodiment 2

A semiconductor device and a method for fabricating the same according to Embodiment 2 of the invention will now be described with reference to the accompanying drawings. In Embodiment 2 of the invention, a semiconductor device and a fabrication method obtained by applying the semiconductor device and the method for fabricating the same according to Embodiment 1 of the invention for lowering the gate line resistance to an SRAM forming region will be described.

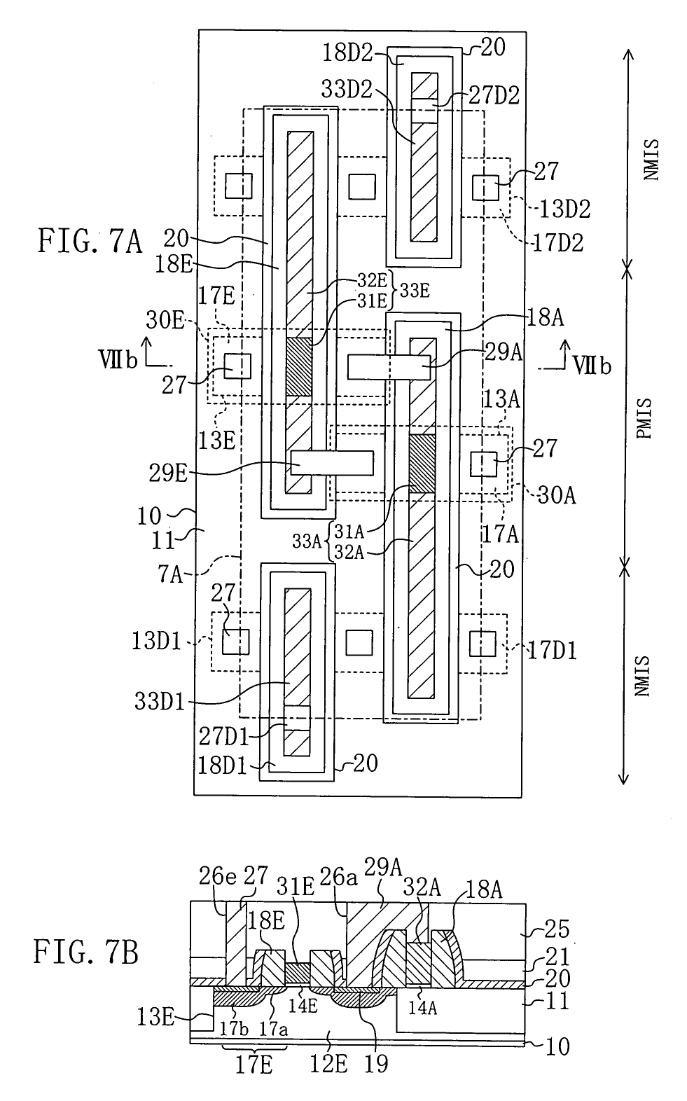

First, the structure of the semiconductor device of Embodiment 2 of the invention will be described with reference to FIGS. 7A and 7B.

FIGS. 7A and 7B are diagrams for explaining the structure of the semiconductor device of this embodiment, and specifically, FIG. 7A is a plan view thereof and FIG. 7B is a cross-sectional view thereof taken on line VIIb-VIIb of FIG. 7A. It is noted that part of the structure correspondingly shown in FIG. 7B is omitted in FIG. 7A for convenience of the explanation.

As shown in the plan view of FIG. 7A, a first active region 13A included in a p-type MIS transistor forming region 30A, a second active region 13E included in a p-type MIS transistor forming region 30E and a third active region 13D1 and a fourth active region 13D2 included in n-type MIS transistor forming regions are formed in a semiconductor substrate 10 of, for example, silicon so as to be surrounded with an isolation region 11.

On the first active region 13A and the isolation region 11, a first fully silicided gate pattern 33A obtained by fully siliciding a gate pattern silicon film is formed so as to extend over the first active region 13A along the gate width direction. The first fully silicided gate pattern 33A includes a first fully silicided gate electrode 31A included in a p-type MIS transistor formed on the first active region 13A and made of a fully silicided material of, for example, Ni₂Si, Ni₃Si or Ni₃₁Si₁₂, and a first fully silicided gate line 32A formed on the isolation region 11 and made of a fully silicided material of, for example, NiSi. The first fully silicided gate electrode 31A and the first fully silicided gate line 32A are continuously and integrally formed.

On the second active region 13E and the isolation region 11, a second fully silicided gate pattern 33E obtained by fully siliciding a gate pattern silicon film is formed so as to extend over the second active region 13E along the gate width direction and to be adjacent to the first fully silicided gate pattern 33A along the gate length direction. The second fully silicided gate pattern 33E includes a second fully silicided gate electrode 31E included in a p-type MIS transistor formed on the second active region 13E and made of a fully silicided material of, for example, Ni₂Si, Ni₃Si or Ni₃₁Ni₁₂, and a second fully silicided gate line 32E made of a fully silicided material of, for example, NiSi and formed on the isolation region 11 to be continuously and integrally with the second fully silicide gate electrode 31E.

A first sidewall 18A made of, for example, a silicon nitride film is formed on the side face of the first fully silicided gate pattern 33A, and a second sidewall 18E made of, for example, a silicon nitride film is formed on the side face of the second fully silicided gate pattern 33E. An underlying protection film 20 is formed on the side faces of the first sidewall 18A and the second sidewall 18E. A p-type first source/drain region is formed in a portion of the first active region 13A disposed on a side of and below the first sidewall 18A, and a p-type second source/drain region 17E is formed in a portion of the second active region 13E disposed on a side of and below the second sidewall 18E.

The first silicided gate pattern 33A extends to cross the third active region 13D1, a third fully silicided gate pattern 33D1 made of a fully silicided material of, for example, NiSi is formed so as to be adjacent to and spaced from the crossing portion along the gate length direction and to cross the third active region 13D1, and a third sidewall 18D1 made of, for example, a silicon nitride film and an underlying protection film 20 are formed on the side face of the third fully silicided gate pattern 33D1. Similarly, the second fully silicided gate pattern 33E extends to cross the fourth active region 13D2, and a fourth fully silicided gate pattern 33D2 made of a fully silicided material of, for example, NiSi and having, on the side face thereof, a fourth sidewall 18D2 and an underlying protection film 20 is formed so as to be adjacent to and spaced from the crossing portion along the gate length direction and to cross the fourth active region 13D2. At this point, a portion of the first fully silicided gate line 32A of the first silicided gate pattern 33A disposed on the third active region 13D1 and a portion of the first fully silicided gate line 32E of the second silicided gate pattern 33E disposed on the fourth active region 13D2 function as fully silicided gate electrodes. Also, portions of the third fully silicided gate pattern 33D1 and the fourth fully silicided gate pattern 33D2 disposed on the third active region 13D1 and the fourth active region 13D2 function as fully silicided gate electrodes, and portions thereof disposed on the isolation region 11 function as fully silicided gate lines.

Furthermore, n-type third source/drain regions 17D1 are formed in portions of the third active region 13D1 disposed on sides of and below the first fully silicided gate pattern 33A and the third fully silicided gate pattern 33D1. Similarly, n-type fourth source/drain regions 17D2 are formed in portions of the fourth active region 13D2 disposed on sides of and below the second fully silicided gate pattern 33E and the fourth fully silicided gate pattern 33D2. Thus, a first n-type MIS transistor is constructed by the third active region 13D1 and the first fully silicided gate pattern 33A, a second n-type MIS transistor is constructed by the fourth active region 13D2 and the second fully silicided gate pattern 33E, a third n-type MIS transistor is constructed by the third active region 13D1 and the third fully silicided gate pattern 33D1, and a fourth n-type MIS transistor is constructed by the fourth active region 13D2 and the fourth fully silicided gate pattern 33D2.

A silicide layer not shown (but shown with a reference numeral of 19 in FIG. 7B mentioned below) is formed in surface portions of the first through fourth source/drain regions 17A, 17E, 17D1 and 17D2, and contact plugs 27 connected to the first through fourth source/drain regions 17A, 17E, 17D1 and 17D2 through the silicide layer are formed so as to penetrate the underlying protection film 20 and first and second interlayer insulating films not shown (but shown with reference numerals of 21 and 25 in FIG. 7B mentioned below). Furthermore, on the first fully silicided gate pattern 33A and the second source/drain region 17E, a shared contact plug 29A connected to the silicide layer formed in the surface portion of the second source/drain region 17E and the first fully silicided gate line 32A is formed, and similarly, on the second fully silicided gate pattern 33E and the first source/drain region 17A, a shared contact plug 29E connected to the silicide layer formed in the surface portion of the first source/drain region 17A and the second fully silicided gate line 32E is formed. In the third fully silicided gate pattern 33D1 and the fourth fully silicided gate pattern 33D2, gate contact plugs 27D1 and 27D2 are formed so as to penetrate the second interlayer insulating film. It is noted that each of the contact plug 27, the shared contact plugs 29A and 29E and the gate contact plugs 27D1 and 27D2 is formed by filling a conducting material such as tungsten in a contact hole.

The above described structure is built in an SRAM forming region 7A including a PMIS forming region where the p-type MIS transistor is formed and NMIS forming regions sandwiching the PMIS forming region in each of which the n-type MIS transistor is formed as shown in FIG. 7A.

Furthermore, in the cross-sectional view of FIG. 7B, an n-type well 12E included in the second active region 13E surrounded with the isolation region 11 is formed in the semiconductor substrate 10. The first fully silicided gate line 32A included in the first fully silicided gate pattern 33A is formed on the isolation region 11 with a first gate insulating film 14A of, for example, a silicon oxide film sandwiched therebetween. The second fully silicided gate electrode 31E included in the second fully silicided gate pattern 33E is formed on the second active region 13E with a second gate insulating film 14E of, for example, a silicon oxide film sandwiched therebetween.

P-type source/drain regions (p-type extension regions or p-type LDD regions) 17a with a comparatively small junction depth are formed in upper portions of the second active region 13E disposed on a side of and below the second fully silicided gate electrode 31E (namely, beneath the second sidewall 18E) and on a side of and below the first fully silicided gate line 32A (namely, beneath the first sidewall 18A). Also, the first sidewall 18A is formed on the side face of the first fully silicided gate line 32A, and the second sidewall 18E is formed on the side face of the second fully silicided gate electrode 31E. At this point, as shown in FIG. 7B, the height of a portion of the second sidewall 18E disposed above the second active region 13E is smaller than the height of a portion of the first sidewall 18A disposed on the isolation region 11 and is the same as the height of a portion of the first sidewall 18A disposed above the first active region 13A. Furthermore, the height of portions of the second sidewall 18E disposed above the fourth active region 17D2 and on the isolation region 11 is larger than the height of a portion of the second sidewall 18E disposed above the second active region 13E and is the same as the height of a portion of the first sidewall 18A disposed on the isolation region 11.

P-type source/drain regions 17b with a comparatively large junction depth are formed in upper portions of the second active region 13E disposed on an outer side of and below the second sidewall 18E and on an outer side of and below the first sidewall 18A. The p-type source/drain region 17a with a comparatively small junction depth and the p-type source/drain region 17b with a comparatively large junction depth together form the second source/drain region 17E.

The silicide layer 19 is formed in upper portions of the second source/drain region 17E disposed on a side of and below the second sidewall 18E and on a side of and below the first sidewall 18A. The underlying protection film 20 made of, for example, a silicon nitride film is formed on the isolation region 11, and the silicide layer 19 and on the side faces of the first fully silicided gate line 32A and the second fully silicided gate electrode 31E.

The first interlayer insulating film 21 made of, for example, a silicon oxide film is formed on the underlying protection film 20. The second interlayer insulating film 25 made of, for example, a silicon oxide film is formed on the first interlayer insulating film 21 so as to cover the first sidewall 18A, the second sidewall 18E, the first fully silicided gate line 32A and the second fully silicided gate electrode 31E. The contact plug 27 made of a conducting material such as tungsten and connected to one of the second source/drain regions 17E through the silicide layer is formed in the second interlayer insulating film 25, the first interlayer insulating film 21 and the underlying protection film 20. On the first fully silicided gate line 32A and the other of the second source/drain regions 17E, a shared contact plug 29A connected to the silicide layer 19 formed in the surface portion of this second source/drain region 17E and the first fully silicided gate line 32A is formed. Although the structure of the p-type MIS transistor formed on the first active region 13A of FIG. 7A is not shown in FIG. 7B, the description is omitted because the structure is similar to that of the p-type MIS transistor shown in FIG. 7B. Also, although the structures of the n-type MIS transistors formed on the third active region 13D1 and the fourth active region 13D2 shown in FIG. 7A are not shown in FIG. 7B, the description is omitted because the structure is similar to that of the n-type MIS transistor shown in FIG. 1B.

In the semiconductor device of Embodiment 2 of the invention having the structure described above, the fully silicided material of, for example, Ni₂Si, Ni₃Si or Ni₃₁Si₁₂ with high interconnect resistance is used as the material for merely the first fully silicided gate electrode 31A provided on the first active region 13A where the p-type MIS transistor is formed and the second fully silicided gate electrode 31E provided on the second active region 13E where the p-type MIS transistor is formed, and the fully silicided material of, for example, NiSi is used as the material for the first fully silicided gate line 32A and the second fully silicided gate line 32E provided on the third active region 17D1 and the fourth active region 17D2 where the n-type MIS transistors are formed and on the isolation region 11. Therefore, the interconnect resistance is low and the resistance of the shared contact can be lowered. Furthermore, in forming the first and second fully silicided gate lines 32A and 32E with low resistance on the isolation region 11, the third active region 17D1 and the fourth active region 17D2, there is no need to etch for thinning the polysilicon used as the gate electrode silicon film. Therefore, the first and second sidewalls 18A and 18E formed on the side faces of the first and second fully silicided gate lines 32A and 32E do not recede during the etching, and hence, there is no fear of the punch through to the semiconductor substrate 10 during the formation of the shared contact plugs 29A and 29E, which otherwise increases a junction leakage current or lowers a junction breakdown voltage. As a result, a semiconductor device with high reliability can be obtained.

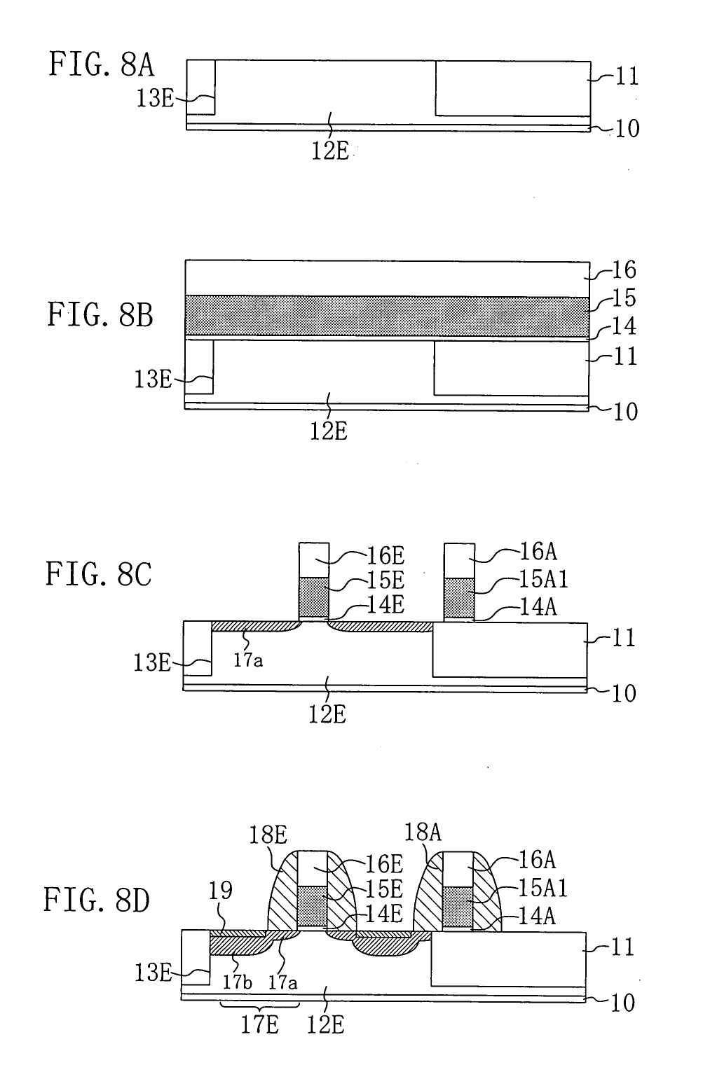

A method for fabricating the semiconductor device of Embodiment 2 of the invention will now be described with reference to FIGS. 8A through 8D, 9A through 9D, 10, 11 and 12A through 12D. In the following description, fabrication procedures up to the formation of the cross-sectional structure shown in FIG. 7B, which principally corresponds to the characteristic of this embodiment, will be described, and specific explanation of fabrication procedures for the rest will be omitted because they can be easily performed by appropriately referring to the following description and the description given in Embodiment 1.

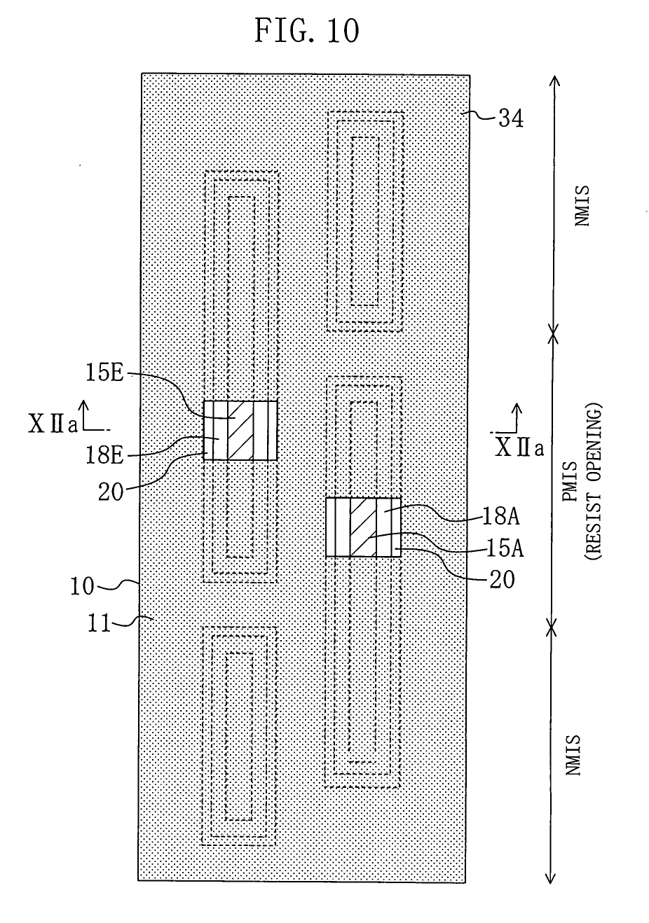

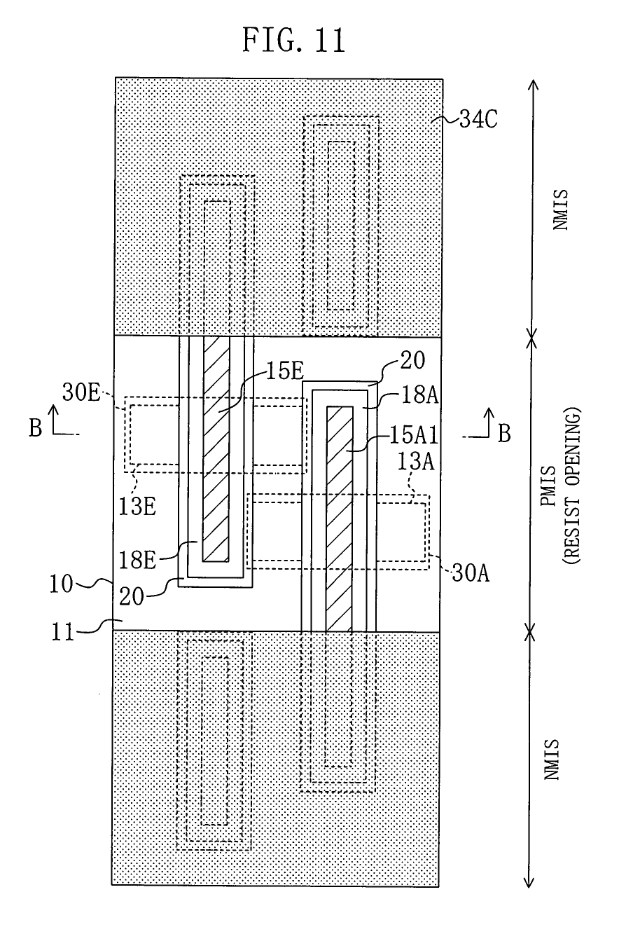

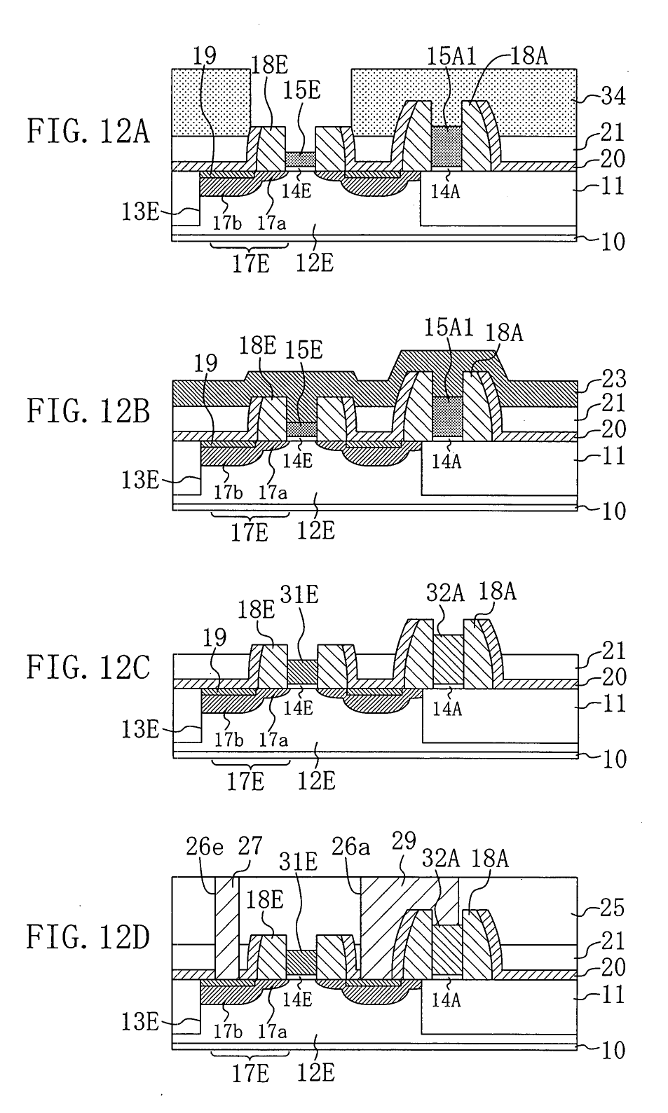

FIGS. 8A through 8D, 9A through 9D and 12A through 12D are cross-sectional views for showing procedures in the method for fabricating a semiconductor device according to Embodiment 2 of the invention, FIG. 10 is a plan view of an opening pattern of a resist mask pattern used in the procedure of FIG. 12A and FIG. 11 is a plan view of an opening pattern of a conventional resist mask pattern mentioned as a comparative example.

First, as shown in FIG. 8A, an isolation region 11 for electrically isolating a device is formed in a surface portion of a semiconductor substrate 10 of, for example, silicon by the STI (shallow trench isolation) method or the like. Next, an n-type well 12E is formed in the semiconductor substrate 10 by the photolithography and the ion implantation. Thus, a second active region 13E corresponding to a device forming region, included in a p-type MIS transistor forming region 30E (see FIG. 7A) and surrounded with the isolation region 11 is formed on the principal plane of the semiconductor substrate 10.

Next, as shown in FIG. 8B, a gate insulating forming film 14 with a thickness of 2 nm made of, for example, a silicon oxide film is formed over the semiconductor substrate 10, and a silicon film 15 with a thickness of 100 nm made of, for example, polysilicon is deposited on the gate insulating forming film 14 by the CVD (chemical vapor deposition) or the like. Subsequently, a protection film 16 with a thickness of 70 nm made of, for example, a silicon oxide film is formed on the silicon film 15 by the CVD or the like.

Then, as shown in FIG. 8C, the gate insulating forming film 14, the silicon film 15 and the protection film 16 are selectively etched by the photolithography and the dry etching. In this selective etching, the gate insulating forming film 14, the silicon film 15 and the protection film 16 are patterned so as to remain in regions corresponding to first and second fully silicided gate patterns 33A and 33E and third and fourth fully silicided gate patterns 33D1 and 33D2 shown in FIG. 7A to be formed later, so that gate pattern silicon films having the same plane shapes as the fully silicided gate patterns 33A, 33E, 33D1 and 33D2 can be formed. Thus, a first gate insulating film 14A, a first gate line silicon film 15A1 functioning as a gate line and a first protection film 16A all patterned by the etching are formed in the isolation region 11, and a second gate insulating film 14E, a second gate electrode silicon film 15E and a second protection film 16E all patterned by the etching are formed on the second active region 13E.

Subsequently, a p-type impurity is ion implanted by using the second gate electrode silicon film 15E and the second protection film 16E as a mask, so as to form p-type source/drain regions (p-type extension regions or p-type LDD regions) 17a with a comparatively small junction depth in portions of the second active region 13E disposed on both sides of and below the second gate electrode silicon film 15E. Although not shown in the drawing, p-type source/drain regions (p-type extension regions or p-type LDD regions) with a comparative small junction depth are formed at this point in portions of the first active region 13A disposed on both sides of and below the first gate electrode silicon film continuous to the first gate line silicon film 15A.

Next, as shown in FIG. 8D, after depositing a silicon nitride film with a thickness of, for example, 50 nm over the semiconductor substrate 10 by the CVD or the like, the deposited silicon nitride film is subjected to the anisotropic etching, so as to form a first sidewall 18A on the side faces of the first gate line silicon film 15A1 and the first protection film 16A and to form a second sidewall 18E on the side faces of the second gate electrode silicon film 15E and the second protection film 16E.

Subsequently, after ion implanting a p-type impurity by using the first sidewall 18A and the second sidewall 18E as a mask, annealing is performed. Thus, p-type source/drain regions 17b with a comparatively large junction depth are formed in portions of the second active region 13E disposed on both sides of and below the second sidewall 18E. Thereafter, annealing is performed at a temperature of 1000° C. or more so as to electrically activating the ion implanted impurity. Thus, the p-type source/drain region 17a with a comparatively small junction depth and the p-type source/drain region 17b with a comparatively large junction depth together form a second source/drain region 17E.

Then, after removing natural oxide from the surface of the second source/drain region 17E, a metal film (not shown) with a thickness of 10 nm made of, for example, nickel is deposited on the semiconductor substrate 10 by the spattering or the like. Subsequently, the semiconductor substrate 10 is subjected to first RTA (rapid thermal annealing) in a nitrogen atmosphere at a temperature of 320° C. for causing a reaction between silicon and the metal film, so as to nickel silicide a surface portion of the second source/drain region 17E. Then, the resultant semiconductor substrate 10 is immersed in an etchant made of a mixed solution of sulfuric acid and hydrogen peroxide water, so as to remove unreacted portions of the metal film remaining on the isolation region 11, the first protection film 16A, the second protection film 16E, the first sidewall 18A, the second sidewall 18E and the like. Thereafter, the semiconductor substrate 10 is subjected to second RTA at a higher temperature (of, for example, 550° C.) than in the first RTA. Thus, a silicide layer 19 with low resistance is formed in the surface portion of the second source/drain region 17E.

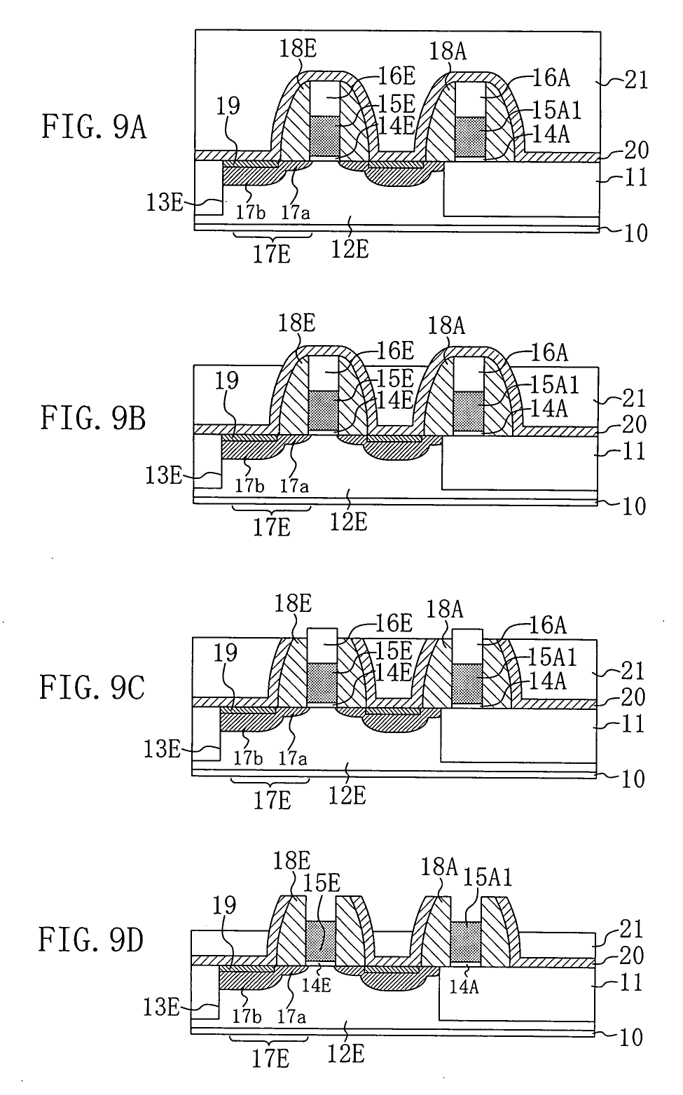

Next, as shown in FIG. 9A, an underlying protection film 20 with a thickness of 20 nm made of, for example, a silicon nitride film is deposited over the semiconductor substrate 10 by the CVD or the like, and a first interlayer insulating film 21 of, for example, a silicon oxide film is formed on the deposited underlying protection film 20. Subsequently, the surface of the first interlayer insulating film 21 is planarized by the CMP (chemical mechanical polishing).

Then, as shown in FIG. 9B, the first interlayer insulating film 21 is etched by the dry etching or wet etching performed under conditions set for attaining high selectivity against a silicon nitride film until portions of the underlying protection film 20 disposed on the first protection film 16A and the second protection film 16E are exposed.

Next, as shown in FIG. 9C, the first protection film 16A and the second protection film 16E are exposed by removing the portions of the underlying protection film 20 disposed thereon by the dry etching or wet etching performed under conditions set for attaining high selectivity against a silicon oxide film.

Thereafter, as shown in FIG. 9D, the top faces of the first gate line silicon film 15A1 and the second gate electrode silicon film 15E are exposed by removing portions of the first protection film 16A and the second protection film 16E formed thereon by the dry etching or wet etching performed under conditions set for attaining high selectivity against a silicon nitride film and a polysilicon film.

Next, as shown in FIGS. 10 and 12A (whereas FIG. 12A is a cross-sectional view taken on line XIIa-XIIa of FIG. 10), a resist mask pattern 34 having an opening pattern for exposing the second gate electrode silicon film 15E, the second sidewall 18E and the upper end of the underlying protection film 20 disposed on the second active region 13E and for exposing the first gate electrode silicon film 15A, the first sidewall 18A and the upper end of the underlying protection film 20 disposed on the first active region 13A is formed over the semiconductor substrate 10 by the photolithography. Subsequently, the second gate electrode silicon film 15E is etched by the dry etching apart from a portion thereof covered by the resist mask pattern 34, so as to reduce its thickness to approximately 40 nm (whereas the first gate electrode silicon film 15A is also similarly thinned at this point). It is noted that the underlying protection film 20, the first sidewall 18A and the upper portion of the second sidewall 18E exposed in the opening pattern of the resist mask pattern 34 are also removed by the etching at this point. Therefore, the height of the first sidewall 18A provided on the first active region 13A and the height of the second sidewall 18E provided on the second active region 13E from the surface of the semiconductor substrate 10 are smaller than the height of the first sidewall 18A and the second sidewall 18E provided on the isolation region 11.

In this manner, since the resist mask pattern 34 having the aforementioned opening pattern is used in this procedure, merely a second fully silicided gate electrode 31E provided on the second active region 13E and a first fully silicided gate electrode 31A provided on the first active region 13A can be made of a fully silicided material of Ni₂Si, Ni₃Si or Ni₃₁Si₁₂ as described later, and hence the resistance of a shared contact can be lowered. Furthermore, since a portion of the first interlayer insulating film 21 buried between the first gate line silicon film 15A1 and the second gate electrode silicon film 15E and the first sidewall 18A provided on the isolation region 11 are covered by the resist mask pattern 34 and not removed by the etching, the thickness reduction of this portion of the first interlayer insulating film 21 and the first sidewall 18A provided on the isolation region 11 can be prevented. In the conventional technique, as shown in a comparative example of FIG. 11, a resist mask pattern 34C for exposing a PMIS forming region (shown as PMIS) sandwiched between NMIS forming regions (shown as NMIS) is used, more portions subsequently formed are made of the fully silicided material of, for example, Ni₂Si, Ni₃Si or Ni₃₁Si₁₂ and hence the interconnect resistance is high. On the contrary, since the resist mask pattern 34 is used in this procedure, the resistance of the shared contact can be obviously lowered. Moreover, in the conventional resist mask pattern 34C, the portion of the first interlayer insulating film 21 buried between the first gate line silicon film 15A1 and the second gate electrode silicon film 15E and the first sidewall 18A provided on the isolation region 11 are exposed in the opening pattern of the resist pattern mask 34C, and hence, the film thickness of this portion of the first interlayer insulating film 21 and the first sidewall 18A provided on the isolation region is reduced. It is noted that the application of the conventional resist pattern 34C to the structure of this embodiment is shown in the plan view of FIG. 11, and that the cross-sectional structure taken on line B-B corresponds to the cross-sectional structure shown in FIG. 12A excluding the resist pattern 34.

Next, as shown in FIG. 12B, a metal film 23 with a thickness of 100 nm of, for example, nickel is deposited on the first interlayer insulating film 21 by, for example, the spattering so as to cover the first gate electrode silicon film 15A and the second gate electrode silicon film 15E.

Then, as shown in FIG. 12C, the semiconductor substrate 10 is subjected to first RTA in a nitrogen atmosphere at a temperature of 380° C., so as to silicide the first gate line silicon film 15A1 and the second gate electrode silicon film 15E. Subsequently, the semiconductor substrate 10 is immersed in an etchant made of a mixed solution of sulfuric acid and hydrogen peroxide water, so as to remove unreacted portions of the metal film remaining on the first interlayer insulating film 21, the underlying protection film 20, the first sidewall 18A, the second sidewall 18E and the like. Thereafter, the semiconductor substrate 10 is subjected to second RTA performed at a higher temperature (of, for example, 500° C.) than in the first RTA. Thus, the first gate line silicon film 15A1 and the second gate electrode silicon film 15E are fully silicided, so as to form the second fully silicided gate electrode 31E made of a fully silicided material of, for example, Ni₂Si, Ni₃Si or Ni₃₁Si₁₂ and to form the first fully silicided gate electrode 32A made of a fully silicided material of, for example, NiSi.

Then, as shown in FIG. 12D, a second interlayer insulating film 25 is deposited over the semiconductor substrate 10 by the CVD or the like, and subsequently, the surface of the second interlayer insulating film 25 is planarized by the CMP. Thereafter, after forming a resist mask pattern (not shown) on the second interlayer insulating film 25, the second interlayer insulating film 25, the first interlayer insulating film 21 and the underlying protection film 20 are dry etched, so as to form a second contact hole 26e reaching the silicide layer 19 formed in the surface portion of one of the second source/drain regions 17E and to form a first contact hole 26a reaching the first fully silicided gate line 32A and the silicide layer 19 formed in the surface portion of the other of the second source/drain regions 17E.

Subsequently, after removing the resist mask pattern (not shown), titanium (Ti) and titanium nitride (TiN) respectively corresponding to an adhesive layer and a barrier metal layer (not shown) are deposited on the semiconductor substrate 10 respectively in thicknesses of 10 nm and 5 nm by the CVD. Thereafter, a metal film of tungsten or the like is deposited on the deposited barrier metal layer. Then, a portion of the metal film deposited on the second interlayer insulating film 25 outside the first contact hole 26a and the second contact hole 26e is removed by the CMP or etch back. Thus, a contact plug 27 connected to one of the second source/drain regions 17E through the silicide layer 19 and a shared contact plug 29 connected to the other of the second source/drain regions 17E and the first fully silicided gate line 32A through the silicide layer 19 are formed.

In the aforementioned method for fabricating a semiconductor device according to Embodiment 2 of the invention, the fully silicided material of, for example, Ni₂Si, Ni₃Si or Ni₃₁Si₁₂ with high interconnect resistance is used as the material for merely the first fully silicided gate electrode 31A provided on the first active region 13A where the p-type MIS transistor is formed and the second fully silicided gate electrode 31A provided on the second active region 13E where the p-type MIS transistor is formed, and the fully silicided material of, for example, NiSi is used as the material for the first fully silicided gate line 32A and the second fully silicided gate line 32E provided on the isolation region 11. Therefore, the interconnect resistance is low and the resistance of the shared contact can be lowered. Furthermore, in forming the first and second fully silicided gate lines 32A and 32E with low resistance on the isolation region 11, there is no need to etch for thinning the polysilicon used as the gate line silicon film. Therefore, the first and second sidewalls 18A and 18E formed on the side faces of the first and second fully silicided gate lines 32A and 32E do not recede during the etching, and hence, there is no fear of the punch through to the semiconductor substrate 10 during the formation of the shared contact plugs 29A and 29E, which otherwise increases a junction leakage current or lowers a junction breakdown voltage. As a result, a semiconductor device with high reliability can be obtained.

In this embodiment, although the length along the gate width direction of the opening pattern of the resist mask pattern 34 shown in FIGS. 10 and 12A preferably accords with the width along the gate width direction of the second source/drain region 17E (the second active region 13E), the length of the opening pattern is not limited to this but may be increased along the gate width direction as far as the second fully silicided gate electrode 31E included in the p-type MIS transistor formed on the second active region 13E can be made of a fully silicided material of, for example, Ni₂Si, Ni₃Si or Ni₃₁Si₁₂ as described above.

In this embodiment, a device other than a transistor may be formed, and an impurity diffusion layer connected to the shared contact plug is not limited to a source/drain region but may be, for example, an impurity diffusion layer where a diode is formed.

Although the gate insulating forming film 14 is made of a silicon oxide film in each of Embodiments 1 and 2, a high dielectric constant film may be used instead. When a high dielectric constant film is used in such a fully silicided gate electrode structure, the threshold voltage is highly controllable depending upon the silicide composition of the material for a fully silicided gate electrode. As the high dielectric constant film, a film made of a hafnium-based oxide such as hafnium oxide (HfO₂), hafnium silicate (HfSiO) or hafnium silicate nitride (HfSiON) can be used. Alternatively, a high dielectric constant film made of a material including at least one of zirconium (Zr), titanium (Ti), tantalum (Ta), aluminum (Al) and rare earth metals such as scandium (Sc), yttrium (Y), lanthanum (La) and other lanthanoids may be used.

Furthermore, although polysilicon is used as the material for the silicon film 15 in each of Embodiments 1 and 2, another semiconductor material or the like including amorphous silicon or silicon may be used instead.

Although nickel is used as the metal for forming the silicide layer 19 in each of Embodiments 1 and 2, another metal for siliciding such as cobalt, titanium or tungsten may be used instead.

Although nickel (Ni) is used as the metal for forming a fully silicided gate electrode in each of Embodiments 1 and 2, another metal for fully siliciding including at least one of cobalt (Co), platinum (Pt), titanium (Ti), ruthenium (Ru), iridium (Ir), ytterbium (Yb) and transition metals may be used instead.

Although each sidewall is made of a single layered film of a silicon nitride film in each of Embodiments 1 and 2, it may be made of a multilayered film of a silicon oxide film and a silicon nitride film instead.

According to the present invention, with respect to a semiconductor device employing fully silicided gate process with a small gate line width, a semiconductor device including a gate line with low interconnect resistance and a method for fabricating the same can be realized. Therefore, the invention is useful for a semiconductor device and a method for fabricating the same in which a gate electrode is fully silicided.

What is claimed is:

1. The semiconductor device comprising a p-type MIS transistor formed on a first active region surrounded by an isolation region in a semiconductor substrate,
the p-type MIS transistor including:
a first gate insulating film formed on the first active region; and
a first fully silicided gate pattern that is obtained by fully siliciding a silicon film, is formed to extend over the first active region with the first gate insulating film sandwiched therebetween, and includes a first fully silicided gate electrode provided on the first active region and a first fully silicided gate line provided on the isolation region,
the first fully silicided gate pattern including, along a gate width direction, a portion that has a first thickness and includes the first fully silicided gate electrode and portions that have a second thickness larger than the first thickness and are respectively disposed on both sides of the portion having the first thickness.

2. The semiconductor device of claim 1,
wherein the portion having the first thickness corresponds to the first fully silicided gate electrode, and
the portion having the second thickness corresponds to the first fully silicided gate line.

3. The semiconductor device of claim 1, further comprising:
a first sidewall formed on a side face of the first fully silicided gate pattern; and
a p-type impurity diffusion region formed in a portion of the first active region disposed on a side of the first sidewall,
wherein the first sidewall has a smaller height on the side face of the portion having the first thickness than on the side face of the portion having the second thickness.

4. The semiconductor device of claim 1, further comprising:
an n-type MIS transistor formed on a second active region surrounded with the isolation region in the semiconductor substrate,
wherein the n-type MIS transistor includes:
a second gate insulating film formed on the second active region; and
a second fully silicided gate electrode that is formed on the second gate insulating film to be adjacent to the first fully silicided gate electrode along the gate width direction and includes an extended portion of the first fully silicided gate line present on the second gate insulating film, and
the second fully silicided gate electrode has a thickness the same as the second thickness.

5. The semiconductor device of claim 4, further comprising:
a second sidewall formed on a side face of the second fully silicided gate electrode; and
an n-type impurity diffusion region formed in a portion of the second active region disposed on a side of the second sidewall,
wherein the second sidewall has the same height as a portion of the first sidewall formed on the side face of the portion having the second thickness.

6. The semiconductor device of claim 1, further comprising an n-type MIS transistor formed on a second active region surrounded with the isolation region in the semiconductor substrate,
wherein the n-type MIS transistor includes:
a second gate insulating film formed on the second active region; and
a second fully silicided gate electrode that is obtained by fully siliciding a silicon film and is formed on the second gate insulating film to be adjacent to the first fully silicided gate electrode along the gate length direction, and
the second fully silicided gate electrode has a thickness the same as the second thickness.

7. The semiconductor device of claim 6, further comprising:
a second sidewall formed on a side face of the second fully silicided gate electrode; and
an n-type impurity diffusion region formed in a portion of the second active region disposed on a side of the second sidewall,
wherein the second sidewall has the same height as a portion of the first sidewall formed on the side face of the portion having the second thickness.

8. The semiconductor device of claim 3, further comprising:
a second fully silicided gate pattern that is obtained by fully siliciding a silicon film and is formed on the isolation region in the semiconductor substrate; and
a shared contact plug connected to the p-type impurity diffusion region and the second fully silicided gate pattern,
wherein the second fully silicided gate pattern has a thickness the same as the second thickness.

9. The semiconductor device of claim 8, further comprising a second sidewall formed on a side face of the second fully silicided gate pattern,
wherein the second sidewall has the same height as a portion of the first sidewall formed on the side face of the portion having the second thickness.

10. The semiconductor device of claim 8, further comprising an additional p-type MIS transistor formed on a second active region surrounded with the isolation region in the semiconductor substrate,
wherein the second fully silicided gate pattern is formed to extend over the second active region with a second gate insulating film formed on the second active region sandwiched therebetween, and
a portion of the second fully silicided gate pattern disposed on the second active region corresponds to a fully silicided gate electrode of the additional p-type MIS transistor.

11. A method for fabricating a semiconductor device, comprising the steps of:
(a) forming a first active region surrounded with an isolation region in a semiconductor substrate;
(b) successively forming a gate insulating forming film, a silicon film and a protection film on the semiconductor substrate and patterning at least the silicon film and the protection film, whereby forming a first gate pattern silicon film patterned from the silicon film and a first protection film patterned from the protection film to extend over the first active region;
(c) forming a first sidewall on a side face of the first gate pattern silicon film;
(d) forming a first p-type impurity diffusion region in a portion of the first active region disposed on a side of the first sidewall through ion implantation of a p-type impurity by using the first sidewall as a mask;
(e) exposing the first gate pattern silicon film by removing the first protection film after the step (d);
(f) reducing a thickness of the first gate pattern silicon film on the first active region to be smaller than on the isolation region through etching using a resist mask pattern covering the isolation region and having a first opening pattern correspondingly to the first active region after the step (e); and
(g) forming a metal film on the first gate pattern silicon film, and fully siliciding the first gate pattern silicon film by annealing the metal film, whereby forming a first fully silicided gate pattern including a first fully silicided gate electrode disposed on the first active region and a first fully silicided gate line disposed on the isolation region after the step (f).

12. The method for fabricating a semiconductor device of claim 11,
wherein the resist mask pattern covers the first p-type impurity diffusion region out of the first active region and has the first opening pattern correspondingly to the first gate pattern silicon film and the first sidewall in the step (f).

13. The method for fabricating a semiconductor device of claim 11,
wherein the step (a) includes a sub-step of forming a second active region surrounded with the isolation region in the semiconductor substrate,
the first gate pattern silicon film and the first protection film are formed to extend over the second active region in the step (b),
the step (d) includes a sub-step of forming an n-type impurity diffusion region in a portion of the second active region disposed on a side of the first sidewall through ion implantation of an n-type impurity by using the first sidewall as a mask, and
the first fully silicided gate pattern including the first fully silicided gate electrode, the first fully silicided gate line and a second fully silicided gate electrode disposed on the second active region is formed in the step (g).

14. The method for fabricating a semiconductor device of claim 11,
wherein the step (a) includes a sub-step of forming a second active region surrounded with the isolation region in the semiconductor substrate,
the step (b) includes a sub-step of forming a second gate pattern silicon film patterned from the silicon film and a second protection film patterned from the protection film to extend over the second active region and to be adjacent to and spaced from the first gate pattern silicon film and the first protection film along a gate length direction,
the step (c) includes a sub-step of forming a second sidewall on a side face of the second gate pattern silicon film,
the step (d) includes a sub-step of forming an n-type impurity diffusion region in a portion of the second active region disposed on a side of the second sidewall through ion implantation of an n-type impurity by using the second sidewall as a mask,
the step (e) includes a sub-step of exposing the second gate pattern silicon film by removing the second protection film, and
the step (g) includes a sub-step of forming the metal film on the second gate pattern silicon film and fully siliciding the second gate pattern silicon film by annealing the metal film, whereby forming a second fully silicided gate pattern including a second fully silicided gate electrode disposed on the second active region and a second fully silicided gate line disposed on the isolation region.

15. The method for fabricating a semiconductor device of claim 11,
wherein the step (b) includes a sub-step of forming a second gate pattern silicon film patterned from the silicon film and a second protection film patterned from the protection film on the isolation region to be adjacent to and spaced from the first gate pattern silicon film and the first protection film along a gate length direction,
the step (c) includes a sub-step of forming a second sidewall on a side face of the second gate pattern silicon film,
the step (e) includes a sub-step of exposing the second gate pattern silicon film by removing the second protection film,
the step (g) includes a sub-step of forming the metal film on the second gate pattern silicon film and fully siliciding the second gate pattern silicon film by annealing the metal film, whereby forming a second fully silicided gate pattern, and
the method further includes, after the step (g), a step (h) of forming a shared contact connected to the p-type impurity diffusion region and the second fully silicided gate pattern.

16. The method for fabricating a semiconductor device of claim 15,
wherein the step (a) includes a sub-step of forming a second active region surrounded with the isolation region in the semiconductor substrate,
the step (d) includes a sub-step of forming a second p-type impurity diffusion region in a portion of the second active region disposed on a side of the second sidewall through ion implantation of a p-type impurity by using the second sidewall as a mask,
a thickness of the second gate pattern silicon film is reduced on the second active region to be smaller than on the isolation region through etching using the resist mask pattern having a second opening pattern correspondingly to the second active region in the step (f), and
the second fully silicided gate pattern including a second fully silicided gate line disposed on the isolation region and a second fully silicided gate electrode disposed on the second active region is formed in the step (g).
